(19) United States
(12) Patent Application Publication
(10) Pub. No.: US 2026/0243937 A1
(43) Pub. Date: Aug. 20, 2026

(54) WAVELENGTH SELECTIVE ABSORPTION FILTER AND ORGANIC ELECTROLUMINESCENT DISPLAY DEVICE

(71) Applicant: FUJIFILM Corporation, Tokyo (JP)

(72) Inventors: Ryota USAMI, Minamiashigara-shi (JP); Kunihiro ATSUMI, Minamiashigara-shi (JP); Nobutaka FUKAGAWA, Minamiashigara-shi (JP); Atsushi AZUMA, Minamiashigara-shi (JP); Daisuke SASAKI, Minamiashigara-shi (JP)

(73) Assignee: FUJIFILM Corporation, Tokyo (JP)

(21) Appl. No.: 19/640,471

(22) Filed: Apr. 7, 2026

Related U.S. Application Data
(63) Continuation of application No. PCT/JP2024/037609, filed on Oct. 22, 2024.

(30) Foreign Application Priority Data
Oct. 23, 2023 (JP) 2023-181861
Apr. 12, 2024 (JP) 2024-064952
Sep. 30, 2024 (JP) 2024-171213

(51) Int. Cl. G02B 5/22; H10K 59/38; H10K 59/80

(52) U.S. Cl. CPC G02B 5/223; H10K 59/38; H10K 59/8791

(57) ABSTRACT

A wavelength selective absorption filter including a resin and at least four kinds of dyes having different main absorption wavelength ranges, in which among the dyes, a dye A having a main absorption wavelength range on a longest wavelength side has a main absorption wavelength range of 600 nm or more and less than 680 nm, and the wavelength selective absorption filter contains at least three kinds of dyes each having a main absorption wavelength range having main absorption wavelength ranges in a wavelength range of less than 600 nm, as the dyes, other than the dye A among the dyes, and an organic electroluminescent display device includes the wavelength selective absorption filter.

### CROSS-REFERENCE TO RELATED APPLICATIONS

This application is a Continuation of PCT International Application No. PCT/JP2024/037609 filed on Oct. 22, 2024, which claims priority under 35 U.S.C. § 119 (a) to Japanese Patent Application No. 2023-181861 filed in Japan on Oct. 23, 2023, Japanese Patent Application No. 2024-064952 filed in Japan on Apr. 12, 2024, and Japanese Patent Application No. 2024-171213 filed in Japan on Sep. 30, 2024. Each of the above applications is hereby expressly incorporated by reference, in its entirety, into the present application.

### BACKGROUND OF THE INVENTION

### 1. Field of the Invention

The present invention relates to a wavelength selective absorption filter and an organic electroluminescent display device.

### 2. Description of the Related Art

An organic electroluminescent (OLED) display device is a device that displays an image by utilizing self-luminescence of an OLED element. Therefore, the OLED display device has advantages such as a high contrast ratio, a high color reproducibility, a wide viewing angle, high-speed responsiveness, and a reduction in thickness and weight can be achieved, as compared with various display devices such as a liquid crystal display device and a plasma display device. In addition to these advantages, in terms of flexibility as well, research and development are being actively carried out as a next-generation display device.

On the other hand, in a case where the OLED display device is used in an external light environment such as outdoors, external light is reflected on a metal electrode or the like constituting the OLED display device, and display defects such as a decrease in contrast occur. A technique of suppressing external light reflection by providing a circular polarization plate including an optically anisotropic layer such as a λ/4 retardation film is known, but in this technique, a problem of a decrease in brightness occurs.

In recent years, a technique of suppressing a decrease in brightness while suppressing external light reflection by providing a light absorbing layer capable of absorbing external light has been studied.

For example, in WO2021/014973A, as a wavelength selective absorption filter in an OLED display device, a wavelength selective absorption filter containing four kinds of dyes each having absorption at different wavelengths such that a specific relationship of absorbance is satisfied.

### SUMMARY OF THE INVENTION

On the other hand, in suppression of external light reflection, not only a magnitude of an external light reflectance but also suppression of an influence of a reflection tint of the external light on an inherent tint of an image display device is required.

In WO2021/014973A, by mixing four kinds of dyes having a main absorption wavelength range in a wavelength range that does not substantially overlap with wavelengths of B (Blue, 460 nm), G (Green, 520 nm), and R (Red, 620 nm), which are used as a light emitting source of the OLED display device, and adjusting a tint, both external light reflection and a decrease in brightness are suppressed at a certain level by the wavelength selective absorption filter, and a tint change depending on the presence or absence of the wavelength selective absorption filter can be suppressed.

However, as a result of repeated studies by the present inventors, it has been found that, in the OLED display device having a color filter, the influence of the reflection tint on the inherent tint of the display image can be suppressed by the wavelength selective absorption filter described in WO2021/014973A (that is, the tint change of the display image is less likely to occur), but in the OLED display device having no color filter, which realizes full color by a three-color separation method, the influence of the reflection tint on the inherent tint of the display image is increased.

Therefore, an object of the present invention is to provide a wavelength selective absorption filter and an organic electroluminescent display device including the same, in which both suppression of a decrease in brightness and suppression of an influence of a reflection tint on an inherent tint of a display image are realized at a high level even in a case of being applied to an organic electroluminescent display device having no color filter.

As a result of intensive studies in consideration of the above-described object, the present inventors have found that the above-described object can be achieved by using a wavelength selective absorption filter containing, as a dye having a main absorption wavelength range on a longest wavelength side, a dye A having a main absorption wavelength range in a region of 600 nm or more and less than 680 nm, which has been considered to be disadvantageous from the viewpoint of suppressing a decrease in brightness because the dye A corresponds to a wavelength range of R (Red, 620 nm) used as a light emitting source of the OLED display device. That is, the present inventors have found that, by using the wavelength selective absorption filter containing the dye A as a dye having a main absorption wavelength range on the longest wavelength side, even in the OLED display device having no color filter, the suppression effect of a decrease in brightness can be realized to be equal to or more than that of the wavelength selective absorption filter in the related art, and the influence of the reflection tint on the inherent tint of the display image can be suppressed at a high level. Further studies have been carried out based on these findings, whereby the present invention has been completed.

That is, the above-described object has been achieved by the following means.

<1>

A wavelength selective absorption filter comprising: a resin; and at least four kinds of dyes having different main absorption wavelength ranges, in which among the dyes, a dye A having a main absorption wavelength range on a longest wavelength side has a main absorption wavelength range of 600 nm or more and less than 680 nm, and the wavelength selective absorption filter contains at least three kinds of dyes each having a main absorption wavelength range having main absorption wavelength ranges in a wavelength range of less than 600 nm, as the dyes, other than the dye A among the dyes.

<2>

The wavelength selective absorption filter according to <1>, in which the dye A is an indoaniline dye represented by General Formula (1).

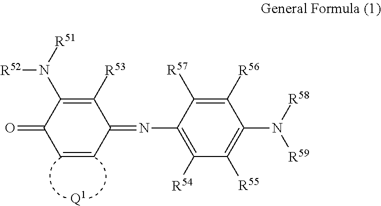

In the formula, Q¹ represents an atomic group that contains at least one nitrogen atom and is necessary for forming a 5- to 7-membered nitrogen-containing heterocyclic ring together with carbon atoms to which Q¹ is bonded.

R⁵¹ represents an acyl group, an alkoxycarbonyl group, an aryloxycarbonyl group, an aminocarbonyl group, or a sulfonyl group, R⁵² represents a hydrogen atom or an alkyl group, R⁵³ to R⁵⁷ represent a hydrogen atom, an alkyl group, an alkoxy group, an acylamino group, an alkylsulfonylamino group, or a halogen atom, and R⁵⁸ and R⁵⁹ represent a hydrogen atom, an alkyl group, or an aryl group.

R⁵¹ and R⁵³, R⁵⁴ and R⁵⁵, and/or R⁵⁵ and R⁵⁹, or R⁵⁸ and R⁵⁹ may be bonded to each other to form a ring.

<3>

An organic electroluminescent display device comprising: the wavelength selective absorption filter according to <1> or <2>.

In the present invention, in a case where there are a plurality of substituents, linking groups, and the like (hereinafter, referred to as substituents and the like) represented by specific reference numerals or formulae, or in a case where a plurality of substituents and the like are defined at the same time, the respective substituents and the like may be the same as or different from each other unless otherwise specified. The same applies to the definition of the number of substituents or the like. In a case where a plurality of substituents or the like come close to each other (particularly in a case where a plurality of substituents or the like are adjacent to each other), the substituents or the like may be linked to each other to form a ring unless otherwise specified. In addition, unless otherwise specified, rings, for example, alicyclic rings, aromatic rings, and heterocyclic rings may be further fused to form a fused ring.

In the present invention, unless otherwise specified, one type of a component (such as a dye, a resin, and other components) forming the wavelength selective absorption filter may be contained in the wavelength selective absorption filter, and two or more types thereof may be contained.

In the present invention, a polymer may be any of a chain polymerization polymer or a condensation polymerization polymer, and may be any of a homopolymer or a copolymer. In addition, in the case of copolymer, any of a random polymer, a block polymer, or the like may be used.

In the present invention, in a case where an E type double bond and a Z type double bond are present in a molecule, the double bond may be any one thereof or may be a mixture thereof, unless otherwise specified.

In the present invention, the representation of a compound (including a complex) is used to mean not only the compound itself but also a salt thereof, and an ion thereof. In addition, it is meant to include those in which a part of the structure is changed, as long as the effect of the present invention is not impaired. Further, a compound for which substitution or non-substitution is not specified means that the compound may have an arbitrary substituent within a range in which an effect of the present invention is not impaired. The same applies to the definition of a substituent or a linking group.

In addition, in the present invention, the numerical range represented by using “to” means a range including the numerical values before and after “to” as the lower limit value and the upper limit value, respectively.

In the present invention, “composition” includes a mixture in which a component concentration varies within a range in which a desired function is not impaired, in addition to a mixture in which the component concentration is constant (respective components are uniformly dispersed).

In the present invention, the description of “having a main absorption wavelength range at a wavelength XX to YY nm” means that a wavelength at which the maximal absorption is exhibited (that is, the maximal absorption wavelength) is present in a wavelength range of XX to YY nm.

Therefore, in a case where the maximal absorption wavelength is present in the above-described wavelength range, the entire absorption band including this wavelength may be in the above-described wavelength range or may also extend up to the outside of the above-described wavelength range. In addition, in a case where there are a plurality of maximal absorption wavelengths, it suffices that a maximal absorption wavelength at which the highest absorbance is exhibited is present in the above-described wavelength range. That is, the maximal absorption wavelength other than the maximal absorption wavelength at which the highest absorbance is exhibited may be present either inside or outside the above-described wavelength range of XX to YY nm.

In the present invention, the main absorption wavelength range of a dye is a main absorption wavelength range of a dye, which is measured in a state of being a wavelength selective absorption filter. Specifically, in Examples described later, the main absorption wavelength range of the dye is measured in a state of the substrate-attached wavelength selective absorption filter under the conditions described in the section of the maximal absorption value of the wavelength selective absorption filter.

In the present invention, “(meth)acrylate” represents any one or both of acrylate and methacrylate, “(meth)acrylic acid” represents any one or both of acrylic acid and methacrylic acid and “(meth)acryloyl” represents any one or both of acryloyl and methacryloyl.

The wavelength selective absorption filter according to the embodiment of the present invention can achieve both the suppression of a decrease in brightness and the suppression of the influence of the reflection tint on the inherent tint of the display image (that is, the suppression of a change in tint of the display image) at a high level even in a case of being applied to an organic electroluminescent display device not having a color filter.

The organic electroluminescent display device according to the embodiment of the present invention includes the wavelength selective absorption filter according to the embodiment of the present invention, and can achieve both the suppression of a decrease in brightness and the suppression of the influence of the reflection tint on the inherent tint of the display image (that is, the suppression of a change in tint of the display image) at a high level.

### BRIEF DESCRIPTION OF THE DRAWINGS

FIG. 1 is absorption spectra of wavelength selective absorption filters Nos. 101 to 103 and c11 produced in Examples.

FIG. 2 is absorption spectra of wavelength selective absorption filters Nos. 104, 105, and c11 produced in Examples.

FIG. 3 is absorption spectra of wavelength selective absorption filters Nos. 103, 106, and 107 produced in Examples.

FIG. 4 is a reflection spectrum of an OLED display device not having a color filter in a case where a wavelength selective absorption filter No. r01 not containing a dye is used, which is calculated in Examples.

FIG. 5 is a reflection spectrum of an OLED display device having a color filter in a case where a wavelength selective absorption filter No. r01 not containing a dye is used, which is calculated in Examples.

FIG. 6 is an absorption spectrum of a laminate of No. 108 produced in Examples.

### DESCRIPTION OF THE PREFERRED EMBODIMENTS

### [Wavelength Selective Absorption Filter]

A wavelength selective absorption filter according to an embodiment of the present invention contains a resin and at least four kinds of dyes having different main absorption wavelength ranges, in which a main absorption wavelength range of a dye A having a main absorption wavelength range on a longest wavelength side among the dyes is 600 nm or more and less than 680 nm, and at least three kinds of dyes having a main absorption wavelength range in a wavelength range of less than 600 nm are contained as dyes other than the dye A among the dyes.

In the present invention, the main absorption wavelength range of the dye in the wavelength selective absorption filter refers to a main absorption wavelength range of the dye measured in a state of the wavelength selective absorption filter. Specifically, in Examples described later, the measurement is performed under conditions described in the section of Maximal Absorption Value of Wavelength Selective Absorption Filter.

A form of the wavelength selective absorption filter according to the embodiment of the present invention may be any form as long as it can achieve both suppression of a decrease in brightness and suppression of an influence of a reflection tint on an inherent tint of a display image (hereinafter, also simply referred to as “suppression of an influence of a reflection tint”) at a high level even in a case of being applied to an OLED display device not having a color filter. Examples of one aspect of the wavelength selective absorption filter according to the embodiment of the present invention include an aspect in which dyes including dye A are dispersed (preferably dissolved) in a resin. The dispersion may be any type of dispersion, such as a random type or a regular type.

The wavelength selective absorption filter according to the embodiment of the present invention has the above-described configuration, and thus, even in a case of being applied to an OLED display device not having a color filter, it is possible to achieve both suppression of a decrease in brightness and suppression of an influence of a reflection tint on an inherent tint of a display image (hereinafter, also simply referred to as “suppression of an influence of a reflection tint”) at a high level. The reason for this is not clear, but can be considered as follows.

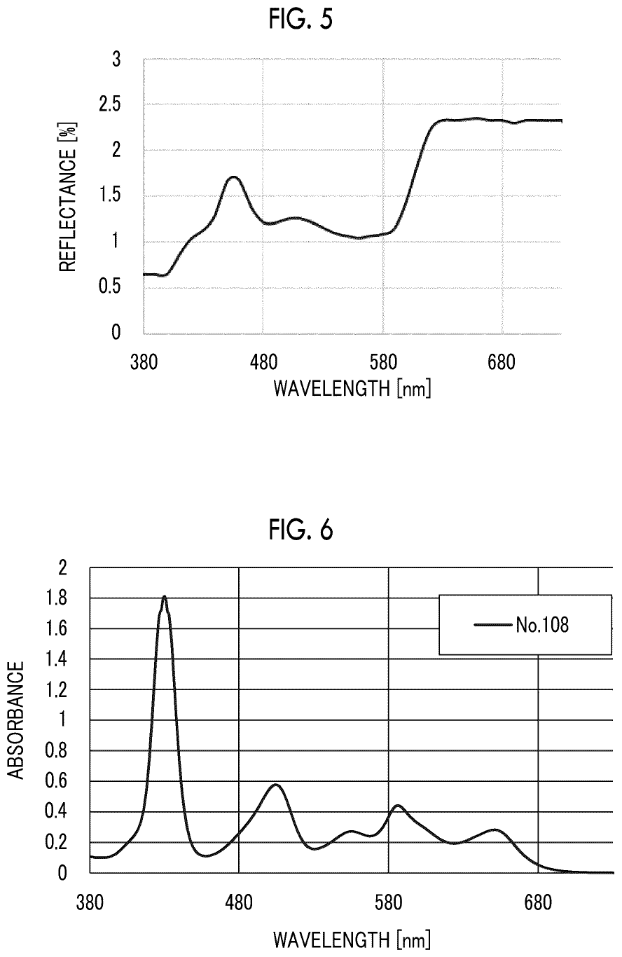

As shown in FIG. 4 described later, in a reflection spectrum of the OLED display device not having a color filter, a reflectance at a wavelength of 580 to 700 nm usually does not change much and is approximately 19%. The wavelength selective absorption filter according to the embodiment of the present invention contains a resin and at least four dyes having different main absorption wavelength ranges, and has a configuration in which the main absorption wavelength range of the dye A having the main absorption wavelength range on the longest wavelength side among the dyes is 600 nm or more and less than 680 nm, and thus, the reflection spectrum at a wavelength of 580 to 700 nm can be adjusted to a right shoulder upward waveform close to the waveform of the reflection spectrum of the OLED display device not having a color filter shown in FIG. 4, and the influence of the reflection tint on the inherent tint of the display image can be suppressed. In addition, according to the wavelength selective absorption filter according to the embodiment of the present invention, even in a right shoulder upward waveform at a wavelength of 590 to 620 nm in a reflection spectrum of the OLED display device having the color filter shown in FIG. 5, the waveform of the reflection spectrum can be made close by containing the dye A, and the influence of the reflection tint on the inherent tint of the display image can be suppressed. The wavelength selective absorption filter according to the embodiment of the present invention can suppress the influence of the reflection tint on the inherent tint of the display image as described above, and furthermore, by combining at least three dyes having a main absorption wavelength range in a wavelength range of less than 600 nm, excluding the dye A, it is possible to suppress a decrease in brightness to the same level or higher than that of the wavelength selective absorption filter in the related art described in WO2021/014973A.

### <Dye>

The wavelength selective absorption filter according to the embodiment of the present invention contains at least four dyes having different main absorption wavelength ranges. In the present invention, the “dye” is not particularly limited as long as it can be dispersed (preferably dissolved) in a resin in the wavelength selective absorption filter, and thus, it is possible to achieve both suppression of a decrease in brightness and suppression of an influence of a reflection tint at a high level even in a case of being applied to an OLED display device not having a color filter.

The wavelength selective absorption filter according to the embodiment of the present invention contains, as the dye having the main absorption wavelength range on the longest wavelength side among the dyes, the dye A in which the main absorption wavelength range is 600 nm or more and less than 680 nm.

The wavelength selective absorption filter according to the embodiment of the present invention contains at least three dyes having a main absorption wavelength range in a shorter wavelength range than the main absorption wavelength range of the dye A, that is, a wavelength range of less than 600 nm. Therefore, in a case where the wavelength selective absorption filter according to the embodiment of the present invention contains at least three dyes having a main absorption wavelength range in a wavelength range of less than 600 nm, the dye A may be one kind or two or more kinds.

It is preferable that the at least three dyes having a main absorption wavelength range in the wavelength range of less than 600 nm described above are dyes including at least one kind of each of the following dyes B, C, and D.
Dye B: a dye having a main absorption wavelength range at a wavelength of 560 nm or more and less than 600 nm in the wavelength selective absorption filter
Dye C: a dye having a main absorption wavelength range at a wavelength of 480 to 520 nm in the wavelength selective absorption filter
Dye D: a dye having a main absorption wavelength range at a wavelength of 390 to 435 nm in the wavelength selective absorption filter

Hereinafter, each of the dyes A to D will be described.

### (Dye A)

The dye A is not particularly limited as long as it has a main absorption wavelength range at a wavelength of 600 nm or more and less than 680 nm in the wavelength selective absorption filter, and various dyes can be used.

The wavelength range in which the dye A has a main absorption wavelength range is preferably 610 to 670 nm, more preferably 615 to 665 nm, and still more preferably 620 to 660 nm.

The dye A is preferably an indoaniline dye represented by General Formula (1).

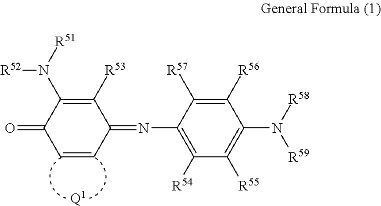

In the formula, Q¹ represents an atomic group that contains at least one nitrogen atom and is necessary for forming a 5- to 7-membered nitrogen-containing heterocyclic ring together with carbon atoms to which Q¹ is bonded.

R⁵¹ represents an acyl group, an alkoxycarbonyl group, an aryloxycarbonyl group, an aminocarbonyl group, or a sulfonyl group, R⁵² represents a hydrogen atom or an alkyl group, R⁵³ to R⁵⁷ represent a hydrogen atom, an alkyl group, an alkoxy group, an acylamino group, an alkylsulfonylamino group, or a halogen atom, and R⁵⁸ and R⁵⁹ represent a hydrogen atom, an alkyl group, or an aryl group.

R⁵¹ and R⁵³, R⁵⁴ and R⁵⁵, and/or R⁵⁵ and R⁵⁹, or R⁵⁸ and R⁵⁹ may be bonded to each other to form a ring. That is, it means that R⁵¹ and R⁵³ may be bonded to each other to form a ring, R⁵⁴ and R⁵⁵ and/or R⁵⁵ and R⁵⁹ may be bonded to each other to form a ring, or R⁵⁸ and R⁵⁹ may be bonded to each other to form a ring.

Regarding the definition and the preferred range of each of the substituents in General Formula (1), unless otherwise specified, the descriptions regarding R¹ to R⁶, R⁸, R⁹, and Q¹ in General Formula (I) described in JP1990-92686A (JP-H2-92686A) can be applied as they are to R⁵¹ to R⁵⁶, R⁵⁸, R⁵⁹, and Q¹, respectively.

It is noted that in the present invention, R⁵³ to R⁵⁶ can adopt the following acylamino group and alkylsulfonylamino group, in addition to the hydrogen atom, the alkyl group, the alkoxy group, and the halogen atom, which can be adopted by R³ to R⁶ regarding General Formula (I) described in JP1990-92686A (JP-H02-92686A).

The number of carbon atoms in the acylamino group that can be adopted as R⁵³ to R⁵⁷ is preferably 1 to 12 and more preferably 1 to 6.

The number of carbon atoms in the alkylsulfonylamino group that can be adopted as R⁵³ to R⁵⁷ is preferably 1 to 12 and more preferably 1 to 6.

To the alkyl group, the alkoxy group, and the halogen atom, which can be adopted as R⁵⁷, the descriptions of the alkyl group, the alkoxy group, and the halogen atom, which can be adopted as R⁵³ to R⁵⁶, can be applied as they are.

Q¹ is preferably represented by —NR¹⁶C(═O)-Q²-. Q² represents an atomic group required for forming a 5- to 7-membered nitrogen-containing heterocyclic ring together with a carbon atom to which —NR¹⁶C(═O)-Q²- is bonded and —NR¹⁶C(═O)—, and examples thereof include a divalent amino group, an ether bond, a thioether bond, an alkylene bond, an ethylene bond, an imino bond, a sulfonyl bond, a carbonyl bond, an arylene bond or a divalent heterocyclic group, and a group obtained by combining a plurality of these. R¹⁶ represents a hydrogen atom, an alkyl group, an aryl group, or a heterocyclic group, where a hydrogen atom is preferable. To each of the definition and the preferred range of each substituent of R¹⁶, the description regarding R¹⁶ regarding General Formula (I) described in JP1990-92686A (JP-H2-92686A) can be applied as it is.

R⁵¹ is preferably an acyl group having 2 to 7 carbon atoms or an alkoxycarbonyl group having 2 to 7 carbon atoms.

R⁵² is preferably a hydrogen atom, and R⁵³ to R⁵⁶ are preferably a hydrogen atom.

R⁵⁷ is preferably an alkoxy group, an acylamino group, or an alkylsulfonylamino group, and more preferably an alkoxy group or an acylamino group.

R⁵⁸ and R⁵⁹ are preferably an alkyl group having 1 to 6 carbon atoms.

Among these, the indoaniline dye represented by General Formula (1) is preferably represented by General Formula (1-a).

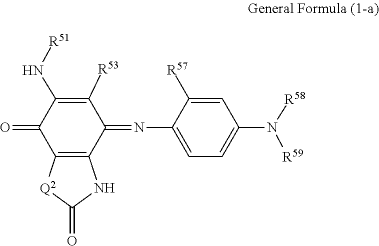

In the formulae, R⁵¹, R⁵³, R⁵⁷ to R⁵⁹, and Q² have the same meanings as R⁵¹, R⁵³, R⁵⁷ to R⁵⁹, and Q² in General Formula (1).

Q² is preferably —CR¹¹R¹²CR¹³R¹⁴—, —CR¹¹R¹²—, or —NR¹¹—, and more preferably —CR¹¹R¹²CR¹³R¹⁴—.

R¹¹ to R¹⁴ represent a hydrogen atom or an alkyl group having 1 to 4 carbon atoms, and it is preferable that R¹¹ and R¹² are a hydrogen atom and R¹³ and R¹⁴ are an alkyl group having 1 to 4 carbon atoms.

It is noted that —CR¹¹R¹²CR¹³R¹⁴— is preferably bonded to >C═O on the side of the carbon atom to which R¹¹ and R¹² are bonded.

Specific examples of the indoaniline dye represented by General Formula (1) include the compounds used in Examples described later and the compounds Nos. 1 to 51 described on pages 5 and 6 of JP1990-92686A (JP-H2-92686A). However, the present invention is not limited thereto.

From the viewpoint that both the suppression of a decrease in brightness and the suppression of the influence of the reflection tint on the inherent tint of the display image in a case of being applied to an organic electroluminescent display device not having a color filter can be realized at a higher level, the dye A is preferably an anthraquinone dye and more preferably an anthraquinone dye represented by General Formula (2).

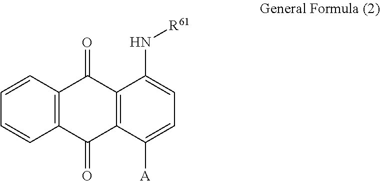

In the formula, A represents a hydroxy group or —NH—R⁶².

R⁶¹ and R⁶² represent a hydrogen atom, an aliphatic hydrocarbon group having 1 to 10 carbon atoms, an alicyclic hydrocarbon group having 3 to 10 carbon atoms, or a group represented by Formula (2b).

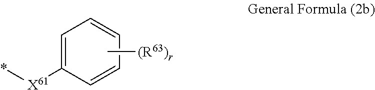

In the formula, R⁶³ represents an alkyl group having 1 to 6 carbon atoms, a halogen atom, —SO₃H, —CO₂H, —CO₂R⁶⁴, —NHCOR⁶⁴, —SO₃R⁶⁴, or —SO₂NR⁶⁴R⁶⁵.

R⁶⁴ represents a saturated hydrocarbon group having 1 to 10 carbon atoms.

R⁶⁵ represents a hydrogen atom or a saturated hydrocarbon group having 1 to 10 carbon atoms.

r represents an integer of 0 to 5.

X⁶¹ represents a single bond or an alkanediyl group having 1 to 6 carbon atoms.

* represents a bonding site.

Examples of the aliphatic hydrocarbon group having 1 to 10 carbon atoms, which can be adopted as R⁶¹ and R⁶², include a methyl group, an ethyl group, a propyl group, a butyl group, a pentyl group, a hexyl group, a heptyl group, an octyl group, a nonyl group, a decyl group, an isopropyl group, an isobutyl group, a sec-butyl group, a tert-butyl group, an isopentyl group, a neopentyl group, and a 2-ethylhexyl group.

Examples of the alicyclic hydrocarbon group having 3 to 10 carbon atoms, which can be adopted as R⁶¹ and R⁶², include a cyclopropyl group, a cyclopentyl group, a cyclohexyl group, a cycloheptyl group, a cyclooctyl group, and a tricyclodecyl group.

The aliphatic hydrocarbon group having 1 to 10 carbon atoms and the alicyclic hydrocarbon group having 3 to 10 carbon atoms, which can be adopted as R⁶¹ and R⁶², may have a substituent, and examples of the substituent which may be contained therein include a hydroxy group and a halogen atom.

Examples of the alkyl group having 1 to 6 carbon atoms, which can be adopted as R⁶³, include a methyl group, an ethyl group, a propyl group, a butyl group, a pentyl group, a hexyl group, an isopropyl group, an isobutyl group, a sec-butyl group, a tert-butyl group, an isopentyl group, and a neopentyl group.

—SO₃H and —CO₂H, which can be adopted as R⁶³, may each have an ion structure in which a hydrogen ion is dissociated, or may have a salt structure. That is, “—CO₂H” is used to mean a group of a carboxylate ion or a salt thereof, and “—SO₃H” is used to mean a group of a sulfonate ion or a salt thereof. Examples of the salt include a salt with an alkali metal such as sodium and potassium; a salt with an alkaline earth metal such as calcium and magnesium; and an ammonium salt.

Examples of the saturated hydrocarbon group having 1 to 10 carbon atoms, which can be adopted as R⁶⁴ and R⁶⁵, include a linear alkyl group such as a methyl group, an ethyl group, a propyl group, a butyl group, a pentyl group, a hexyl group, a heptyl group, an octyl group, a nonyl group, and a decyl group; a branched alkyl group such as an isopropyl group, an isobutyl group, an isopentyl group, a neopentyl group, and a 2-ethylhexyl group; and a saturated alicyclic hydrocarbon group such as a cyclopropyl group, a cyclopentyl group, a cyclohexyl group, a cycloheptyl group, a cyclooctyl group, and a tricyclodecyl group.

At least one hydrogen atom contained in the saturated hydrocarbon group having 1 to 10 carbon atoms, which can be adopted as R⁶⁴ and R⁶⁵, may be substituted with a halogen atom, a hydroxy group, or an amino group.

Examples of —CO₂R⁶⁴ include a methoxycarbonyl group, an ethoxycarbonyl group, a propoxycarbonyl group, a tert-butoxycarbonyl group, a hexyloxycarbonyl group, and an icosyloxycarbonyl group.

Examples of —NHCOR⁶⁴ include an N-acetylamino group, an N-propanoylamino group, an N-butyrylamino group, an N-isobutyrylamino group, and an N-pivaloylamino group.

Examples of —SO₃R⁶⁴ include a methoxysulfonyl group, an ethoxysulfonyl group, a propoxysulfonyl group, a tert-butoxysulfonyl group, a hexyloxysulfonyl group, and an icosyloxysulfonyl group.

Examples of —SO₂NR⁶⁴R⁶⁵ include an N−1 substituted sulfamoyl group such as an N-methylsulfamoyl group, an N-ethylsulfamoyl group, an N-propylsulfamoyl group, an N-isopropylsulfamoyl group, an N-butylsulfamoyl group, an N-isobutylsulfamoyl group, an N-sec-butylsulfamoyl group, an N-tert-butylsulfamoyl group, an N-pentylsulfamoyl group, an N-(1-ethylpropyl) sulfamoyl group, an N-(1,1-dimethylpropyl) sulfamoyl group, an N-(1,2-dimethylpropyl) sulfamoyl group, an N-(2,2-dimethylpropyl) sulfamoyl group, an N-(1-methylbutyl) sulfamoyl group, an N-(2-methylbutyl) sulfamoyl group, an N-(3-methylbutyl) sulfamoyl group, an N-cyclopentylsulfamoyl group, an N-cyclohexylsulfamoyl group, an N-hexylsulfamoyl group, an N-(1,3-dimethylbutyl) sulfamoyl group, an N-(3,3-dimethylbutyl) sulfamoyl group, an N-heptylsulfamoyl group, an N-(1-methylhexyl) sulfamoyl group, an N-(1,4-dimethylpentyl) sulfamoyl group, an N-octylsulfamoyl group, an N-(2-ethylhexyl) sulfamoyl group, an N-(1,5-dimethyl) hexylsulfamoyl group, an N-(1,1,2,2-tetramethylbutyl) sulfamoyl group, and an N-(5-aminopentyl) sulfamoyl group; an N,N-disubstituted sulfamoyl group such as an N,N-dimethylsulfamoyl group, an N-ethyl-N-methylsulfamoyl group, an N,N-diethylsulfamoyl group, an N-propyl-N-methylsulfamoyl group, an N-isopropyl-N-methylsulfamoyl group, an N-tert-butyl-N-methylsulfamoyl group, an N-butyl-N-ethylsulfamoyl group, an N,N-bis(1-methylpropyl) sulfamoyl group, and an N-heptyl-N-methylsulfamoyl group.

Examples of the alkanediyl group having 1 to 6 carbon atoms, which can be adopted as X⁶¹, include a methylene group, an ethylene group, a propane-1,3-diyl group, a propane-1,2-diyl group, a butane-1,4-diyl group, a pentane-1,5-diyl group, a hexane-1,6-diyl group, an ethane-1,1-diyl group, a butane-1,3-diyl group, a 2-methylpropane-1,3-diyl group, a 2-methylpropane-1,2-diyl group, a pentane-1,4-diyl group, and a 2-methylbutane-1,4-diyl group.

Examples of the anthraquinone dye represented by General Formula (2) include exemplary compounds (2-1) to (2-14) shown below. However, the present invention is not limited thereto.

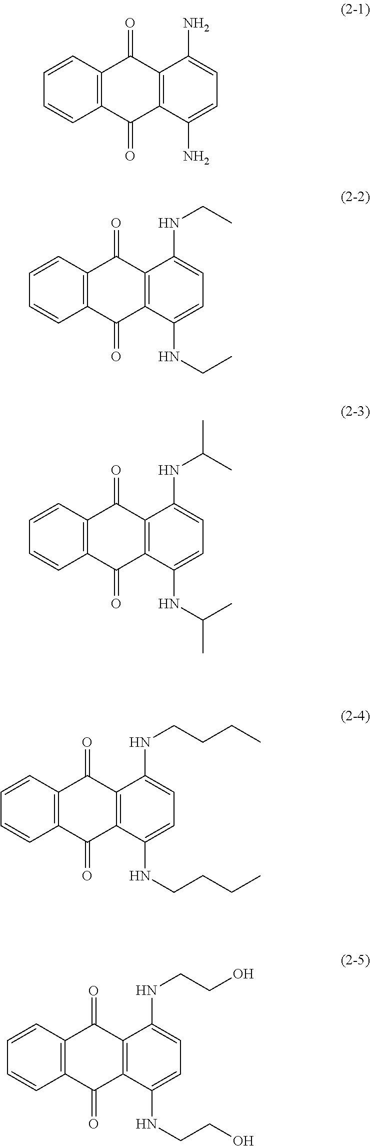

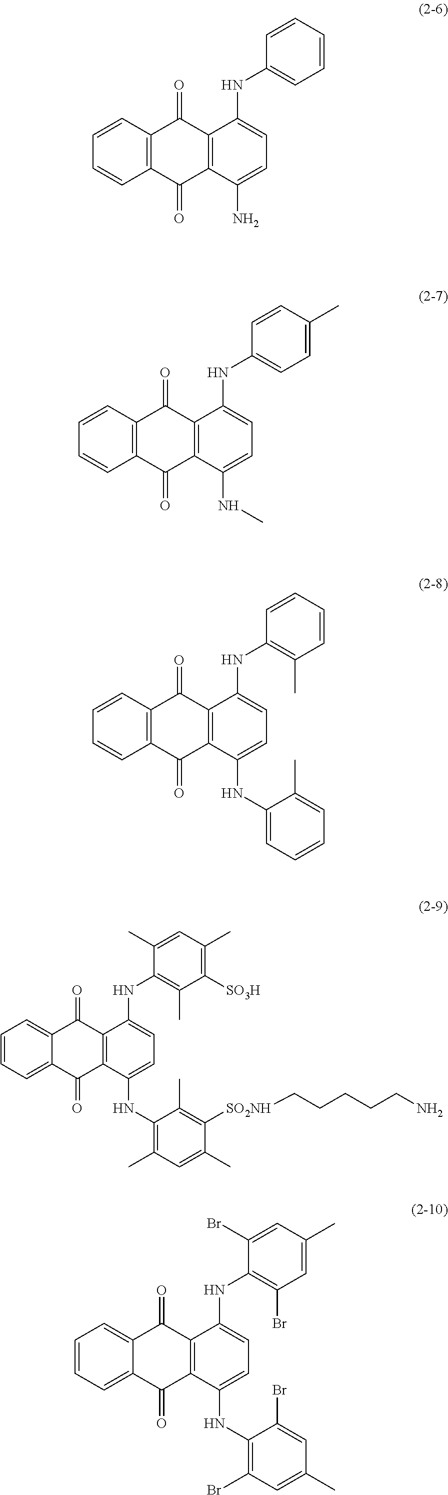

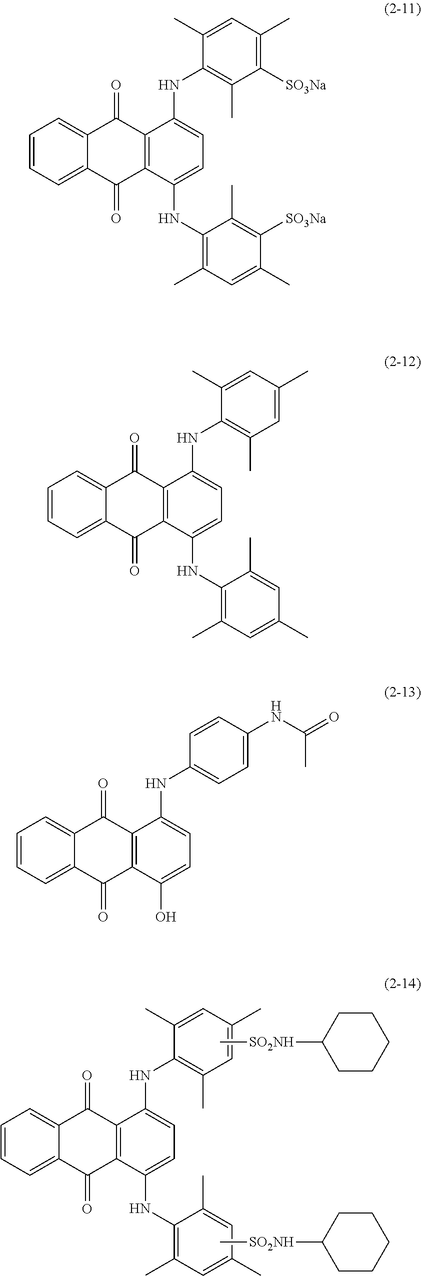

Among these, as the anthraquinone dye represented by General Formula (2), C. I. (Colour Index International) Solvent Blue 35 (the above-described exemplary compound (2-4)), C. I. Solvent Blue 36 (the above-described exemplary compound (2-3)), C. I. Solvent Blue 45 (the above-described exemplary compound (2-14)), C. I. Solvent Blue 63, C. I. Solvent Blue 97, C. I. Acid Blue 80 (the above-described exemplary compound (2-11)), C. I. Solvent Blue 101 (the above-described exemplary compound (2-8)), C. I. Solvent Blue 104 (the above-described exemplary compound (2-12)), and C. I. Solvent Blue 122 (the above-described exemplary compound (2-13)) are preferable.

### (Dye B and Dye C)

The dye B is not particularly limited as long as it has a main absorption wavelength range at a wavelength of 560 nm or more and less than 600 nm in the wavelength selective absorption filter, and various dyes can be used.

The dye C is not particularly limited as long as the dye has the main absorption wavelength range in a wavelength of 480 to 520 nm in the wavelength selective absorption filter, and various dyes can be used.

The wavelength range in which the dye B has a main absorption wavelength range is preferably 560 to 595 nm and more preferably 565 to 595 nm.

In addition, the wavelength range in which the dye C has a main absorption wavelength range is preferably 485 to 520 nm, more preferably 490 to 520 nm, and still more preferably 490 to 515 nm.

Specific examples of the dye B include each coloring agent (dye) of tetraazaporphyrin (TAP), squaraine, azo, and cyanine (CY).

Specific examples of the dye C include each coloring agent (dye) of pyrrole methine (PM), rhodamine (RH), boron dipyrromethene (BODIPY), azo, and squaraine (SQ).

Among these, as the dye B and the dye C, squaraine-based coloring agents are preferable, and squaraine-based coloring agents represented by General Formula (1) are more preferable in that an absorption waveform in the main absorption wavelength range is sharp. By using a coloring agent having a sharp absorption waveform as the dye B and the dye C as described above, the inherent tint of the image of the OLED display device can be maintained at a more excellent level.

That is, in the wavelength selective absorption filter according to the embodiment of the present invention, from the viewpoint of suppressing the tint change, it is preferable that at least one of the dye B or the dye C is a squaraine coloring agent (preferably, a squaraine coloring agent represented by General Formula (1)). In addition, it is also preferable that the dye B is a tetraazaporphyrin coloring agent.

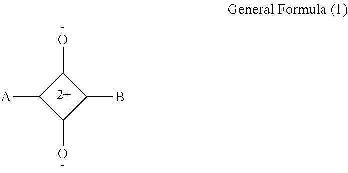

In Formula (1), A and B each independently represent an aryl group which may have a substituent, a heterocyclic group which may have a substituent, or —CH=G. G represents a heterocyclic group which may have a substituent.

With regard to definition and a preferred range of each substituent in General Formula (1), each of descriptions related to each substituent of coloring agents represented by General Formula (1) described in WO2021/132674A can be applied unless otherwise specified.

As the coloring agent represented by General Formula (1), the description regarding the tautomerism structure described in paragraphs 0020 to 0114 of WO2021/132674A, the squaraine-based coloring agent and the quencher-embedded coloring agent represented by any of General Formulae (1) to (9) and the specific examples thereof, and the description regarding the squaraine-based coloring agent represented by General Formula (14) and the specific examples thereof described in paragraphs 0116 to 0126 of WO2022/138925A can be applied as it is.

In addition, the following squaraine coloring agents are also preferable as the dye B.

In addition, the dye 7-23 used in Examples described later is also preferable as the dye C.

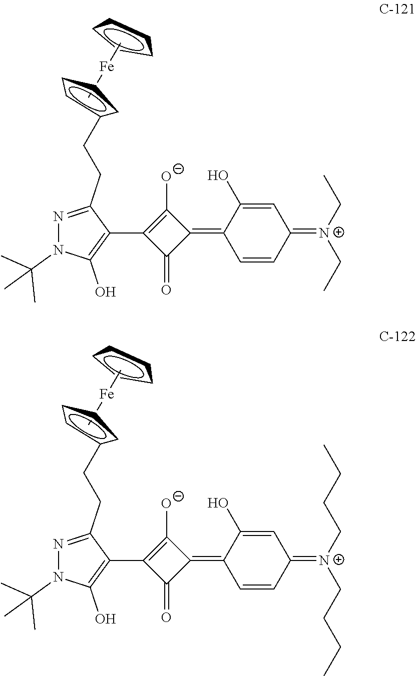

In addition, as the dye B, among the indoaniline dyes represented by General Formula (1) described in the dye A, a dye having a main absorption wavelength range in the wavelength range defined by the dye B can also be used.

A tetraazaporphyrin dye represented by General Formula (8) can also be preferably used as the dye B.

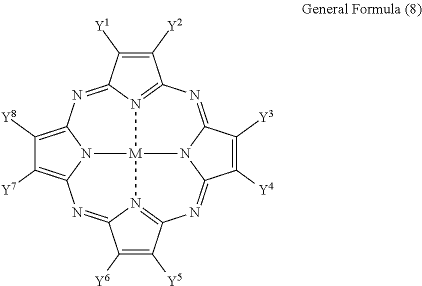

In the formula, Y¹ to Y⁸ represent a hydrogen atom, a halogen atom, a nitro group, a cyano group, a hydroxy group, an amino group (—NH₂), a carboxy group, a sulfonic acid group, an alkyl group having 1 to 20 carbon atoms, an alkoxy group having 1 to 20 carbon atoms, an aryloxy group having 6 to 20 carbon atoms, a monoalkylamino group having 1 to 20 carbon atoms, a dialkylamino group having 2 to 20 carbon atoms, a monoarylamino group having 6 to 20 carbon atoms, a diarylamino group having 12 to 20 carbon atoms, an aralkyl group having 7 to 20 carbon atoms, an aryl group having 6 to 20 carbon atoms, a heteroaryl group, an alkylthio group having 1 to 20 carbon atoms, or an arylthio group having 6 to 20 carbon atoms.

Y¹ to Y⁸ may form an alicyclic ring through a linking group.

M represents two hydrogen atoms, a divalent metal atom, a divalent monosubstituted metal atom, a trivalent substituted metal atom, a tetravalent substituted metal atom, or a metal oxide atom.

In the formula, nitrogen atoms located above and below M on the paper surface indicate that the nitrogen atoms are coordinated to M by an unshared electron pair.

For a description of a halogen atom, an alkyl group having 1 to 20 carbon atoms, an alkoxy group having 1 to 20 carbon atoms, an aryloxy group having 6 to 20 carbon atoms, a monoalkylamino group having 1 to 20 carbon atoms, a dialkylamino group having 2 to 20 carbon atoms, a monoarylamino group having 6 to 20 carbon atoms, a diarylamino group having 12 to 20 carbon atoms, an aryl group having 6 to 20 carbon atoms, a heteroaryl group, an alkylthio group having 1 to 20 carbon atoms, and an arylthio group having 6 to 20 carbon atoms, which can be adopted as Y¹ to Y⁸, the description of a halogen atom, an alkyl group, an alkoxy group, an aryloxy group, an amino group, an aryl group, a heteroaryl group, an alkylthio group, and an arylthio group in a substituent group T described later can be applied by adjusting the number of carbon atoms.

In addition, for an aralkyl group having 7 to 20 carbon atoms, which can be adopted as Y¹ to Y⁸, the description of the substituent group T described later can be applied by adjusting the number of carbon atoms as a group in which an alkyl group in the substituent group T described later is substituted with an aryl group in the substituent group T described later.

The alicyclic ring which may be formed by Y¹ to Y⁸ through a linking group may be an alicyclic hydrocarbon ring or an alicyclic heterocyclic ring. In addition, the group forming an alicyclic ring through a linking group among Y¹ to Y⁸ is not particularly limited, and examples thereof include substituents bonded to the same ring, such as Y¹ and Y², and substituents bonded to adjacent rings, such as Y² and Y³, as two adjacent groups.

The linking group interposed in a case where Y¹ to Y⁸ form an alicyclic ring is not particularly limited, and examples thereof include a divalent group obtained by removing one hydrogen atom from a monovalent substituent in the substituent group T described later.

As Y¹ to Y⁸, a combination in which one of two substituents bonded to the same 5-membered ring is an alkyl group having 1 to 20 carbon atoms and the other is an aryl group having 6 to 20 carbon atoms (preferably an aryl group substituted with a halogen atom or the like) is preferable. Examples of the tetraazaporphyrin dye in which Y¹ to Y⁸ satisfy the above-described preferable combination include FDG-007 (product name, manufactured by Yamada Chemical Co., Ltd., tetraazaporphyrin copper complex dye) used in Examples described later.

In a case where M is two hydrogen atoms, one hydrogen atom is bonded to a nitrogen atom constituting a 5-membered ring to which Y³ and Y⁴ are bonded, and another hydrogen atom is bonded to a nitrogen atom constituting a 5-membered ring to which Y⁷ and Y⁸ are bonded.

Examples of the divalent metal atom which can be adopted as M include copper, magnesium, zinc, cobalt, titanium, iron, vanadium, and vanadium oxide, and copper is preferable.

Examples of the divalent monosubstituted metal atom which can be adopted as M include copper, magnesium, zinc, and iron.

Examples of the trivalent substituted metal atom which can be adopted as M include iron, cobalt, and vanadium.

Examples of the tetravalent substituted metal atom which can be adopted as M include titanium.

Examples of the metal oxide atom which can be adopted as M include vanadium oxide.

In the divalent monosubstituted metal atom, the trivalent substituted metal atom, and the tetravalent substituted metal atom which can be adopted as M, the group which substitutes the metal atom is not particularly limited, and examples thereof include substituents which can be included in the central metal in the tetraazaporphyrin dye, and examples thereof include a halogen atom, an alkoxy group, an aryloxy group, an acyloxy group, a hydroxy group, an alkyl group, an aryl group, an alkylthio group, and an arylthio group.

For example, as the tetraazaporphyrin dye represented by General Formula (8), commercially available products can be used without any limitation, and for example, a tetraazaporphyrin compound satisfying the main absorption wavelength range as a dye B, which is sold by Tokyo Chemical Industry Co., Ltd., Yamada Chemical Co., Ltd., Yamamoto Chemicals, Inc., or the like, can be used.

### (Dye D)

The dye D is not particularly limited as long as the dye has the main absorption wavelength range in a wavelength of 390 to 435 nm in the wavelength selective absorption filter, and various dyes can be used.

A wavelength range of the dye D having a main absorption wavelength range is preferably 395 to 435 nm, more preferably 400 to 435 nm, and still more preferably 405 to 435 nm.

Preferred examples of the dye D include a pyrrole methine dye represented by General Formula (A1) from the viewpoint that the absorption waveform in the main absorption wavelength range is sharp. As the dye represented by General Formula (A1), the description of the coloring agents represented by General Formula (A1) or (A2) and the specific examples described in paragraphs 0022 to 0066 of WO2022/138925A can be applied as they are. In addition, a dye E-42 used in Examples described later is also preferable as the dye D.

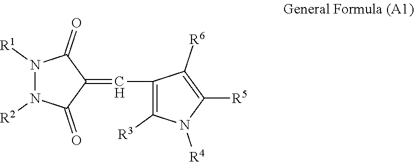

In Formula (A1), R¹ and R² each independently represent an alkyl group or an aryl group, R³ to R⁶ each independently represent a hydrogen atom or a substituent, and R⁵ and R⁶ may be bonded to each other to form a 6-membered ring.

With regard to definition and a preferred range of each substituent in General Formula (A1), each of descriptions related to each substituent of coloring agents represented by General Formula (A1) described in WO2022/138925A can be applied unless otherwise specified.

In addition, preferred examples of the dye D also include a dye represented by General Formula (B). As the dye represented by General Formula (B), the description of the compounds represented by General Formulae (1), (3), or (6) and the specific examples described in paragraphs 0016 to 0097 of WO2023/100715A can be applied as they are. In addition, a dye A-321 used in Examples described later is also preferable as the dye D.

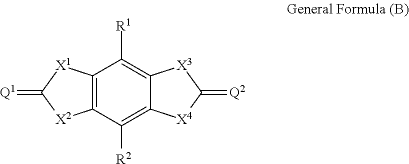

In General Formula (B), Q¹ represents a group represented by Formula (Q-1).

Q² represents ═O, ═S, ═NR^{q1}, or ═CR^{q2}R^{q3}, where Ral to R^{q3} represent a hydrogen atom or a substituent, and R^{q2} and R^{q3} may be bonded to each other to form a ring. However, in a case where R^{q2} and R^{q3} are bonded to each other to form a ring, ═CR^{q2}R^{q3} does not have the same structure as Q¹.

R¹ and R² represent a hydrogen atom or a substituent.

X¹ to X⁴ each independently represent —S—, —NR^{X1}—, or —SO₂—, where R^{X1} represents a hydrogen atom or an alkyl group.

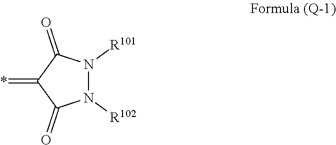

In Formula (Q-1), * represents a bonding site, and R¹⁰¹ and R¹⁰² represent a hydrogen atom, an alkyl group, an aralkyl group, an aryl group, a heterocyclic group, or a group including a polymerizable group having an ethylenically unsaturated bond.

However, in a case where any one of R¹⁰¹ or R¹⁰² is a hydrogen atom, the other is an alkyl group, an aralkyl group, an aryl group, a heterocyclic group, or a group including a polymerizable group having an ethylenically unsaturated bond,
in a case where any one of R¹⁰¹ or R¹⁰² is a methyl group, the other is a hydrogen atom, an alkyl group having 2 or more carbon atoms, an aralkyl group, an aryl group, a heterocyclic group, or a group including a polymerizable group having an ethylenically unsaturated bond, and
in a case where any one of R¹⁰¹ or R¹⁰² is a phenyl group, the other is a hydrogen atom, an alkyl group, an aralkyl group, an aryl group having a substituent, a heterocyclic group, or a group including a polymerizable group having an ethylenically unsaturated bond.

Unless otherwise specified, the definition and the preferred range of each substituent in General Formula (B) can be applied as they are to the description regarding each substituent of the compound represented by General Formula (1) described in WO2023/100715A.

Among these, in the present invention, the dye represented by General Formula (B) is preferably a dye consisting of a combination of the following substituents.

R¹⁰¹ and R¹⁰² are preferably an alkyl group or an aralkyl group, and more preferably an alkyl group having 2 or more carbon atoms.

Q² is —CR^{q2}R^{q3}, and it is preferable that R^{q2} and R^{q3} are bonded to each other to form a cyclopropane ring, a cyclobutane ring, a cyclopentane ring, or a cyclohexane ring, and it is more preferable that R^{q2} and R^{q3} are bonded to each other to form a cyclobutane ring. It is preferable that the ring formed by bonding R^{q2} and R^{q3} to each other is substituted with one or two-O's, and it is more preferable that the ring is further fused with a substituted or unsubstituted benzene ring.

R¹ and R² are preferably —OC(═O)—Y¹¹, —O—Y¹¹, or —OC(═O)NR^{y11}, and more preferably —OC(═O)—Y¹¹. Y¹¹ is preferably an alkyl group, and more preferably a branched alkyl group. R^{y11} is preferably a hydrogen atom or an alkyl group, and more preferably an alkyl group.

X¹ to X⁴ are preferably —S—.

In addition, as the dye D, a porphyrin dye can also be preferably used, and it is more preferable to use a porphyrin dye represented by General Formula (7) which contains copper, magnesium, zinc, cobalt, titanium, iron, vanadium, or vanadium oxide as a central metal.

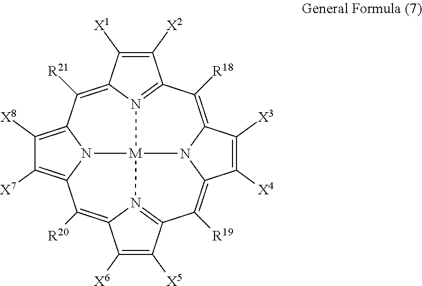

In the formula, X¹ to X⁸ represent a hydrogen atom, a halogen atom, an alkyl group, an alkoxy group, a substituted or unsubstituted ethenyl group, a substituted or unsubstituted ethynyl group, an aryl group, an aryloxy group, an aryloxycarbonyl group, an alkylthio group, an arylthio group, or an acyl group.

Adjacent groups among X¹ to X⁸ may be bonded to each other to form an aromatic ring together with the substituted carbon atoms.

R¹⁸ to R²¹ represent an aryl group.

M represents copper, magnesium, zinc, cobalt, titanium, iron, vanadium, or vanadium oxide.

In the formula, nitrogen atoms located above and below M on the paper surface indicate that the nitrogen atoms are coordinated to M by an unshared electron pair.

For the halogen atom, the alkyl group, the alkoxy group, the aryl group, the aryloxy group, the aryloxycarbonyl group, and the alkylthio group, which can be adopted as X¹ to X⁸, the description of the halogen atom, the alkyl group, the alkoxy group, the aryl group, the aryloxy group, the aryloxycarbonyl group, and the alkylthio group in the substituent group T described later can be applied.

The alkyl group which can be adopted as X¹ to X⁸ may have a substituent, and examples of the alkyl group substituted with a substituent include an aralkyl group, a halogenoalkyl group, an alkoxyalkyl group, an aryloxyalkyl group, an aralkyloxyalkyl group, and a halogenoalkoxyalkyl group. For the substituent in the alkyl group substituted with these substituents, the description of the corresponding substituent in the substituent group T described later or the description of the substituent formed by a combination of a plurality of corresponding substituents in the substituent group T described later can be applied.

The alkoxy group which can be adopted as X¹ to X⁸ may have a substituent, and examples of the alkoxy group substituted with a substituent include an aralkyloxy group and a halogenoalkoxy group. For the substituent in the alkoxy group substituted with these substituents, the description of the corresponding substituent in the substituent group T described later can be applied.

As the substituent which can be contained in the substituted ethenyl group and the substituted ethynyl group, which can be adopted as X¹ to X⁸, the substituent in the substituent group T described later can be applied.

For the aryl group which can be adopted as R¹⁸ to R²¹, the description of the alkyl group in the substituent group T described later can be applied.

Among these, it is preferable that X¹ to X⁸ represent a hydrogen atom, a halogen atom, a linear alkyl group having 1 to 10 carbon atoms, a branched alkyl group having 3 to 10 carbon atoms, or a cyclic alkyl group having 3 to 10 carbon atoms.

In addition, as the porphyrin dye represented by General Formula (7), commercially available products can also be used without any particular limitation, and for example, a porphyrin compound satisfying the main absorption wavelength range as the dye D, which is sold by Tokyo Chemical Industry Co., Ltd., Yamada Chemical Co., Ltd., and the like, can be used. For example, FDB-002 (product name, manufactured by Yamada Chemical Co., Ltd.) used in Examples described later corresponds to the porphyrin dye represented by General Formula (7).

The total content of the above-described dye in the wavelength selective absorption filter according to the embodiment of the present invention is preferably 1.0% to 50% by mass, more preferably 1.5% to 40% by mass, still more preferably 2.0% to 30% by mass, particularly preferably 2.5% to 20% by mass, and especially preferably 3.0% to 15% by mass.

The content of the dye A in the wavelength selective absorption filter according to the embodiment of the present invention is preferably 0.01% to 45% by mass, more preferably 0.1% to 30% by mass, and still more preferably 0.1% to 10% by mass.

In a case where the wavelength selective absorption filter according to the embodiment of the present invention contains the dyes B to D, the content of each of the dyes B to D is preferably 0.01% to 45% by mass, more preferably 0.1% to 30% by mass, and still more preferably 0.1% to 10% by mass.

The content proportion of each of the dyes A to D in the wavelength selective absorption filter is preferably the dyeA:thedyeB:thedyeC:thedyeD=1:0.01 to 10:0.01 to 10:0.1 to 20, and more preferably 1:0.05 to 5:0.1 to 5:0.5 to 10 in terms of mass ratio.

### <Resin>

The resin contained in the above-described wavelength selective absorption filter (hereinafter, also referred to as “matrix resin”) is not particularly limited as long as the above-described dye can be dispersed (preferably dissolved) and both the suppression of a decrease in brightness and the suppression of the influence of the reflection tint on the inherent tint of the display image can be realized at a high level even in a case where the resin is applied to an OLED display device not having a color filter, and the resin has desired light transmittance (the transmittance in a visible region at a wavelength of 400 to 800 nm is preferably 80% or more).

As a polymer that constitutes the above-described resin, various polymers can be used.

Preferred examples thereof include a polymer having an aromatic ring or an alicyclic structure, and a (meth)acrylic polymer containing a constitutional unit having an aromatic ring or an alicyclic structure is more preferable.

Here, the (meth)acrylic polymer refers to a polymer containing at least one of a constitutional unit derived from (meth)acrylic acid or a constitutional unit derived from (meth)acrylic acid ester.

In the present disclosure, the “main chain” represents a relatively longest bonding chain in a molecule of a polymer compound, and the “side chain” represents an atomic group branched from the main chain.

### <<Constitutional Unit Having Aromatic Ring>>

It is also preferable that the polymer constituting the above-described resin has a constitutional unit having an aromatic ring (preferably, an aromatic hydrocarbon ring).

Examples of the constitutional unit having an aromatic ring include a constitutional unit derived from a (meth)acrylate having an aromatic ring, and a constitutional unit derived from benzyl (meth)acrylate, naphthyl (meth)acrylate, phenethyl (meth)acrylate, phenoxyethyl (meth)acrylate, or naphthylmethyl (meth)acrylate is preferable.

In the polymer constituting the above-described resin, a content of the constitutional unit having an aromatic ring is preferably 5 to 100 mol %, more preferably 10 to 100 mol %, and still more preferably 20 to 100 mol % in a case where the total of all constitutional units of the polymer is set to 100 mol %.

One kind of the constitutional unit having an aromatic ring may be used alone, or two or more kinds thereof may be used in combination.

### <<Constitutional Unit Having Alicyclic Structure>>

It is also preferable that the polymer constituting the above-described resin has a constitutional unit having an alicyclic structure.

Examples of the alicyclic structure include a tricyclo[5.2.1.02.6]decane ring structure (also referred to as tetrahydrodicyclopentadiene; the monovalent group is dicyclopentanyl), a tricyclo[5.2.1.02.6]decane-3-ene ring structure (also referred to as 5,6-dihydrodicyclopentadiene; the monovalent group is dicyclopentenyl), an isobornane ring structure (the monovalent group is isobornyl), an adamantane ring structure (the monovalent group is adamantyl), a cyclopentane ring structure, and a cyclohexane ring structure (the monovalent group is cyclohexyl).

Examples of the constitutional unit having an alicyclic structure include a constitutional unit derived from a (meth)acrylate having an alicyclic structure, and a constitutional unit derived from dicyclopentanyl (meth)acrylate, dicyclopentenyl (meth)acrylate, isobornyl (meth)acrylate, adamantyl (meth)acrylate, or cyclohexyl (meth)acrylate is preferable.

In the polymer constituting the above-described resin, a content of the constitutional unit having an alicyclic structure is preferably 1 to 90 mol %, more preferably 5 to 90 mol %, still more preferably 10 to 70 mol %, particularly preferably 20 to 55 mol %, and especially preferably 25 to 55 mol % in a case where the total of all constitutional units of the polymer is set to 100 mol %.

One kind of the constitutional unit having an alicyclic structure may be used alone, or two or more kinds thereof may be used in combination.

### <<Constitutional Unit Having Alkyl Group Having 1 to 14 Carbon Atoms>>

From the viewpoint of adjusting the glass transition temperature, the polymer constituting the above-described resin may include a constitutional unit having an alkyl group having 1 to 14 carbon atoms (excluding an alicyclic alkyl group). Examples of the constitutional unit having an alkyl group having 1 to 14 carbon atoms include a constitutional unit derived from an alkyl (meth)acrylate, such as methyl (meth)acrylate, ethyl (meth)acrylate, n-propyl (meth)acrylate, isopropyl (meth)acrylate, n-butyl (meth)acrylate, t-butyl (meth)acrylate, sec-butyl (meth)acrylate, pentyl (meth)acrylate, 2-ethylhexyl (meth)acrylate, 2-ethylbutyl (meth)acrylate, n-octyl (meth)acrylate, isooctyl (meth)acrylate, isononyl (meth)acrylate, lauryl (meth)acrylate, or tetradecyl (meth)acrylate. In the present invention, one kind of the constitutional unit having an alkyl group having 1 to 14 carbon atoms may be used alone, or two or more kinds thereof may be used in combination.

In the polymer constituting the above-described resin, a content of the constitutional unit having an alkyl group having 1 to 14 carbon atoms is preferably 0 to 95 mol %, more preferably 0 to 70 mol %, still more preferably 0 to 50 mol %, and particularly preferably 0 to 20 mol % in a case where the total of all constitutional units of the polymer is set to 100 mol %.

### <<Constitutional Unit Having Polar Group>>

The polymer constituting the above-described resin may include a constitutional unit having a polar group. Examples of the polar group contained in the polymer constituting the resin include a carboxy group, a hydroxy group (including a phenolic hydroxyl group), a nitrogen-containing aromatic ring group, and an amide group, and a carboxy group is preferable.

The polymer having a polar group, which constitutes the resin, preferably includes a constitutional unit having a polar group, and examples thereof include a constitutional unit derived from a chain polymerization monomer having a polar group and a carbon-carbon double bond, and a constitutional unit derived from (meth)acrylic acid, crotonic acid, itaconic acid, maleic acid, fumaric acid, 4-vinylpyridine, 4-vinylpyrrolidone, 4-vinylphenol, or the like is preferable.

In the polymer constituting the above-described resin, a content of the constitutional unit having a polar group is preferably 0 to 95 mol %, more preferably 0 to 70 mol %, still more preferably 0 to 50 mol %, and particularly preferably 0 to 20 mol % in a case where the total of all constitutional units of the polymer is set to 100 mol %.

### (Cyclic Polyolefin Resin)

As the resin contained in the above-described wavelength selective absorption filter, a cyclic polyolefin resin described below can also be preferably used.

The cyclic olefin compound forming the cyclic polyolefin contained in the cyclic polyolefin resin is not particularly limited as long as the compound has a ring structure including a carbon-carbon double bond, and examples thereof include norbornene compounds; and monocyclic olefin compounds, cyclic conjugated diene compounds, vinyl alicyclic hydrocarbon compounds, which are not norbornene compounds, and the like.

Examples of the cyclic polyolefin include (1) polymers including a structural unit derived from a norbornene compound; (2) polymers including a structural unit derived from a monocyclic olefin compound other than the norbornene compound; (3) polymers including a structural unit derived from a cyclic conjugated diene compound; (4) polymers including a structural unit derived from a vinyl alicyclic hydrocarbon compound; and hydrides of polymers including a structural unit derived from each of the compounds (1) to (4).

In the present invention, ring-opening polymers of the respective compounds are included in the polymers including a structural unit derived from a norbornene compound and the polymers including a structural unit derived from a monocyclic olefin compound.

The cyclic polyolefin is not particularly limited, but a polymer having a structural unit derived from a norbornene compound, which is represented by General Formula (A-II) or (A-III), is preferable. The polymer having the structural unit represented by General Formula (A-II) is an addition polymer of a norbornene compound, and the polymer having the structural unit represented by General Formula (A-III) is a ring-opening polymer of a norbornene compound.

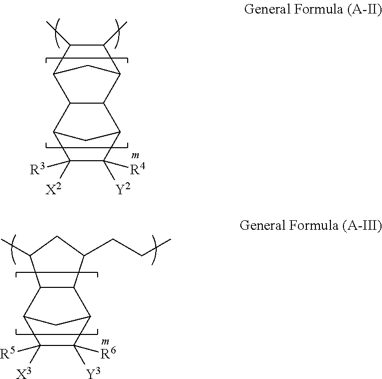

In the formula, m is an integer of 0 to 4, and is preferably 0 or 1.

R³ to R⁶ each independently represent a hydrogen atom or a hydrocarbon group having 1 to 10 carbon atoms.

The hydrocarbon group in General Formula (A-I) and General Formula (A-II) to (A-III) is not particularly limited as long as it is a group consisting of a carbon atom and a hydrogen atom, and examples thereof include an alkyl group, an alkenyl group, an alkynyl group, and an aryl group (aromatic hydrocarbon group). Among these, an alkyl group or an aryl group is preferable.

X² and X³, and Y² and Y³ each independently represent a hydrogen atom, a hydrocarbon group having 1 to 10 carbon atoms, a halogen atom, a hydrocarbon group having 1 to 10 carbon atoms which is substituted by a halogen atom, —(CH₂)ₙCOOR¹¹, —(CH₂)ₙOCOR¹², —(CH₂)ₙNCO, —(CH₂)ₙNO₂, —(CH₂)ₙCN, —(CH₂)ₙCONR¹³R¹⁴, —(CH₂)ₙNR¹³R¹⁴, —(CH₂)ₙOZ or —(CH₂)ₙW, or (—CO)₂O or (—CO)₂NR¹⁵ which is formed by X² and Y² or X³ and Y³ bonded to each other.

Here, R¹¹ to R¹⁵ each independently represent a hydrogen atom or a hydrocarbon group having 1 to 20 carbon atoms, Z represents a hydrocarbon group or a hydrocarbon group substituted with a halogen, W represents Si(R¹⁶)ₚD₍₃₋ₚ₎ (R¹⁶ represents a hydrocarbon group having 1 to 10 carbon atoms, D represents a halogen atom, —OCOR¹⁷, or —OR¹⁷ (R¹⁷ represents a hydrocarbon group having 1 to 10 carbon atoms), and p is an integer of 0 to 3), n is an integer of 0 to 10, and is preferably 0 to 8 and more preferably 0 to 6.

R³ to R⁶ are each preferably a hydrogen atom or —CH₃, and from the viewpoint of moisture permeability, more preferably a hydrogen atom.

X² and X³ are each preferably a hydrogen atom, —CH₃, or —C₂H₅ and more preferably a hydrogen atom in terms of moisture permeability.

Y² and Y³ are each preferably a hydrogen atom, a halogen atom (particularly a chlorine atom), or —(CH₂)ₙCOOR¹¹ (particularly —COOCH₃) and more preferably a hydrogen atom in terms of moisture permeability.

Other groups are appropriately selected.

The polymer having the structural unit represented by Formula (A-II) or (A-III) may further include at least one or more structural units represented by Formula (A-I).

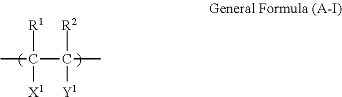

In General Formula (A-I), R¹ and R² each independently represent a hydrogen atom or a hydrocarbon group having 1 to 10 carbon atoms, and X¹ and Y¹ each independently represent a hydrogen atom, a hydrocarbon group having 1 to 10 carbon atoms, a halogen atom, a hydrocarbon group having 1 to 10 carbon atoms, which is substituted with a halogen atom, —(CH₂)ₙCOOR¹¹, —(CH₂)ₙOCOR¹², —(CH₂)ₙNCO, —(CH₂)ₙNO₂, —(CH₂)ₙCN, —(CH₂)ₙCONR¹³R¹⁴, —(CH₂)ₙNR¹³R¹⁴, —(CH₂)ₙOZ, —(CH₂)ₙW, or (—CO)₂O or (—CO)₂NR¹⁵ which is formed by X¹ and Y¹ being bonded to each other.

Here, R¹¹ to R¹⁵ each independently represent a hydrogen atom or a hydrocarbon group having 1 to 20 carbon atoms, Z represents a hydrocarbon group or a hydrocarbon group substituted with a halogen, W represents Si(R¹⁶)ₚD₍₃₋ₚ₎ (R¹⁶ represents a hydrocarbon group having 1 to 10 carbon atoms, D represents a halogen atom, —OCOR¹⁷, or —OR¹⁷ (R¹⁷ represents a hydrocarbon group having 1 to 10 carbon atoms), and p is an integer of 0 to 3), and n is an integer of 0 to 10.

From the viewpoint of adhesiveness, the content of the structural unit derived from the norbornene compound in the cyclic polyolefin having the structural unit represented by General Formula (A-II) or (A-III) is preferably 100% by mass or less, more preferably 30% to 97% by mass, still more preferably 50% to 95% by mass, and most preferably 60% to 90% by mass with respect to the total mass of the cyclic polyolefin. Here, the proportion of the structural unit derived from a norbornene compound represents the average value in the cyclic polyolefin.

The addition (co) polymer of a norbornene compound is described in JP-H10-7732A, JP2002-504184A, US2004/229157A1, and WO2004/070463A.

The polymer of a norbornene compound is obtained by the addition polymerization of norbornene compounds (for example, polycyclic unsaturated compounds of norbornene).

In addition, as the polymer of a norbornene compound, copolymers obtained by the addition copolymerization of, as necessary, a norbornene compound, olefin such as ethylene, propylene, and butene, conjugated diene such as butadiene and isoprene, unconjugated diene such as ethylidene norbornene, and an ethylenically unsaturated compound such as acrylonitrile, acrylic acid, methacrylic acid, maleic acid anhydride, acrylic acid ester, methacrylic acid ester, maleimide, vinyl acetate, and vinyl chloride are exemplified. Among these, a copolymer of a norbornene compound and ethylene is preferable.

Examples of the addition (co) polymers of a norbornene compound include APL8008T (Tg: 70° C.), APL6011T (Tg: 105° C.), APL6013T (Tg: 125° C.), and APL6015T (Tg: 145° C.), which are available from Mitsui Chemicals, Inc. under a product name of APEL and have glass transition temperatures (Tg) different from each other. In addition, pellets such as TOPAS8007, TOPAS6013, and TOPAS6015 are put on the market by Polyplastics Co., Ltd. Further, Appear 3000 is put on the market by Film Ferrania S. R. L.

As the polymer of a norbornene compound, commercially available products can be used. For example, polymers are put on the market by JSR Corporation under a product name of Arton R or Arton F, and polymers are put on the market by Zeon Corporation under a product name of Zeonor ZF14, ZF16, Zeonex 250, or Zeonex 280.

The hydride of the polymer of a norbornene compound can be synthesized by an addition polymerization or a ring-opening metathesis polymerization of a norbornene compound or the like and then an addition of hydrogen. The synthesis method is described in, for example, JP1989-240517A (JP-H1-240517A), JP1995-196736A (JP-H7-196736A), JP1985-26024A (JP-S60-26024A), JP1987-19801A (JP-S62-19801A), JP2003-159767A, JP2004-309979A, and the like.

The weight-average molecular weight (Mw) of the polymer that constitutes the resin is preferably 10,000 or more, more preferably 10,000 to 200,000, and still more preferably 15,000 to 150,000.

In the present invention, the weight-average molecular weight of the polymer can be measured as a molecular weight in terms of polystyrene by gel permeation chromatography (GPC).

Specifically, a GPC device HLC-8220 (trade name, manufactured by Tosoh Corporation) is used, tetrahydrofuran is used as an eluent, G3000HXL+G2000HXL (both are trade names, manufactured by Tosoh Corporation) are used as columns, and detection can be performed by a differential refractive index (RI) at 23° C. and a flow rate of 1 mL/min.

In addition, as an example of another embodiment of the above-described resin, a polystyrene resin is preferable.

The description of the matrix resin described in [0145] to [0189] of WO2021/132674A can be applied. Among these, a polystyrene resin described in [0151] to [0155] of WO2021/132674A can be preferably applied.

A content of the resin in the above-described wavelength selective absorption filter is preferably 50% by mass or more and less than 100% by mass, more preferably 60% by mass or more and less than 100% by mass, and still more preferably 65% by mass or more and less than 100% by mass. The upper limit value thereof is also preferably 99% by mass or less, more preferably 97% by mass or less, still more preferably 95% by mass or less, and particularly preferably 90% by mass or less.

The resin may be used alone or in combination of two or more kinds thereof.

### <Other Components>

The wavelength selective absorption filter according to the embodiment of the present invention may contain a leveling agent (surfactant), an antifading agent described in paragraphs 0245 to 0261 of WO2021/014973A, a matting agent described in paragraphs 0262 to 0264 of WO2021/014973A, and the like.

In addition, in a case where the description of the matrix resin described in to of WO2021/132674A is applied as the resin in the wavelength selective absorption filter according to the embodiment of the present invention, the wavelength selective absorption filter according to the embodiment of the present invention may contain the following association inhibitor.

### (Association Inhibitor)

The wavelength selective absorption filter according to the embodiment of the present invention preferably contains an association inhibitor in order to suppress or prevent the association of the dye molecules in the wavelength selective absorption filter according to the embodiment of the present invention by interacting with the above-described dye. It is preferable that a compound, which exhibits a function of sharpening the absorption waveform of the dyes B to D contained in the wavelength selective absorption filter and improving the light fastness by an association inhibitor, contains the association inhibitor. As the association inhibitor used in the present invention, the association inhibitors described in paragraphs [0177] to [0228] of WO2022/138925A can be used.

The content of the association inhibitor in the wavelength selective absorption filter according to the embodiment of the present invention is preferably 0.1% to 30% by mass, more preferably 1% to 20% by mass, and still more preferably 2% to 15% by mass.

In the wavelength selective absorption filter according to the embodiment of the present invention, the association inhibitor is preferably contained at a proportion of 10 to 1,000 parts by mass, more preferably contained at a proportion of 20 to 700 parts by mass, and still more preferably contained at a proportion of 30 to 500 parts by mass, with respect to 100 parts by mass of the total contents of the dye including the dyes B to D.

### (Leveling Agent)

A leveling agent (surfactant) can be appropriately mixed with the wavelength selective absorption filter according to the embodiment of the present invention. As the leveling agent, a commonly used compound can be used, and a fluorine-containing surfactant is particularly preferable. Specific examples thereof include compounds described in paragraph Nos. [0028] to [0056] of JP2001-330725A; and preferred examples thereof include a copolymer consisting of a constitutional unit having a fluorine-substituted alkyl group and a constitutional unit derived from an alkyl (meth)acrylate, in a copolymer represented by Formula (IV) described in paragraph No. [0054] of JP2001-330725A. In addition, as the commercially available product, MEGAFACE F (product name) series manufactured by DIC Corporation can also be used.

The content of the leveling agent in the wavelength selective absorption filter according to the embodiment of the present invention is appropriately adjusted according to the purpose.

The wavelength selective absorption filter according to the embodiment of the present invention may contain, in addition to the above components, a low-molecular plasticizer, an oligomer-based plasticizer, a retardation modifier, an ultraviolet absorber, a deterioration preventing agent, a peeling accelerator, an infrared absorber, an antioxidant, a filler, and a compatibilizer.

### <Manufacturing Method for Wavelength Selective Absorption Filter>

The wavelength selective absorption filter according to the embodiment of the present invention can be prepared by a solution film-forming method, a melt extrusion method, or a method of forming a coating layer on a substrate film (release film) (coating method) according to a predetermined method, according to a conventional method, and stretching can also be appropriately combined. The wavelength selective absorption filter according to the embodiment of the present invention is preferably prepared by a coating method.

For the solution film-forming method and melt extrusion method described above, the descriptions regarding the solution film-forming method and the melt extrusion method in paragraphs [0268] to [0274] of WO2021/014973A can be applied as they are.

### (Coating Method)

In the coating method, a solution of a material of the wavelength selective absorption filter according to the embodiment of the present invention is applied to a release film to form a coating layer. A release agent or the like may be appropriately applied to the surface of the release film in advance in order to control the adhesiveness to the coating layer. The coating layer can be used by peeling off the release film after being laminated with another member through an adhesion layer in a later step. A predetermined adhesive can be appropriately used as the adhesive constituting the adhesion layer. It is noted that the release film can be appropriately stretched together with the release film coated in a state where a solution of the material of the wavelength selective absorption filter according to the embodiment of the present invention is applied or a coating layer is laminated on the release film.

The solvent that is used for the solution of the wavelength selective absorption filter material can be appropriately selected from the viewpoints that the wavelength selective absorption filter material can be dissolved or dispersed, a uniform surface shape can be easily achieved during the coating step and drying step, liquid preservability can be secured, and a proper saturated vapor pressure is provided.

### —Addition of Dye (Coloring Agent)—

The timing of adding the dye to the material of the wavelength selective absorption filter is not particularly limited as long as the coloring agent is added at the time of film formation. For example, the dye may be added at a time point of synthesizing the matrix resin, or may be mixed with the material of the wavelength selective absorption filter when the coating liquid for the material of the wavelength selective absorption filter is prepared.

### —Release Film—

The release film used for forming the wavelength selective absorption filter by a coating method or the like preferably has a film thickness of 5 to 100 μm, more preferably 10 to 75 μm, and still more preferably 15 to 55 μm. In a case where the film thickness is equal to or larger than the above-described preferred lower limit value, sufficient mechanical strength can be easily secured, and failures such as curling, wrinkling, and buckling are less likely to occur. In addition, in a case where the film thickness is equal to or less than the preferable upper limit value, in the storage of a multilayer film of the release film and the wavelength selective absorption filter according to the embodiment of the present invention, for example, in the aspect of a long roll, the surface pressure applied to the multilayer film is easily adjusted to be in an appropriate range, and adhesion defect is less likely to occur.

The surface energy of the release film is not particularly limited, and in a case of adjusting the relationship between the surface energy of the material of the wavelength selective absorption filter or coating solution and the surface energy of the surface of the release film on which the wavelength selective absorption filter is to be formed, it is possible to adjust the adhesive force between the wavelength selective absorption filter and the release film. In a case where the surface energy difference is reduced, the adhesive force tends to increase, in a case where the surface energy difference is increased, the adhesive force tends to decrease, and thus the surface energy can be set appropriately.

The surface energy of the release film can be calculated from the contact angle value between water and methylene iodide using the method of Owens. For measurement of the contact angle, for example, DM901 (manufactured by Kyowa Interface Science Co., Ltd., contact angle meter) can be used.

The surface energy of the surface of the release film on which the wavelength selective absorption filter is to be formed is preferably 41.0 to 48.0 mN/m and more preferably 42.0 to 48.0 mN/m. In a case where the surface energy is equal to or more than the preferable lower limit value, the evenness of the thickness of the wavelength selective absorption filter is increased. In a case where the surface energy is equal to or less than the preferable upper limit value, it is easy to control the peeling force of the wavelength selective absorption filter from the release film within an appropriate range.

The surface unevenness of the release film is not particularly limited. However, the surface unevenness of the release film can be adjusted in response to the relationship between the surface energy, hardness, and surface unevenness of the surface of the wavelength selective absorption filter, and the surface energy and hardness of the surface of the release film opposite to the side on which the wavelength selective absorption filter is formed, for example, in order to prevent adhesion defect in a case where the multi-layer film of the release film and the wavelength selective absorption filter according to the embodiment of the present invention is stored in the form of a long roll. In a case where the surface unevenness is increased, adhesion defect tends to be suppressed, and in a case where the surface unevenness is reduced, the surface unevenness of the wavelength selective absorption filter tends to be decreased and the haze of the wavelength selective absorption filter tends to be small. Thus, the surface unevenness can be set appropriately.

For such a release film, predetermined materials and films can be appropriately used. Specific examples of the material include a polyester-based polymer (including polyethylene terephthalate-based film), an olefin-based polymer, a cycloolefin-based polymer, a (meth)acrylic polymer, a cellulose-based polymer, and a polyamide-based polymer. In addition, a surface treatment can be appropriately performed for the purpose of adjusting the surface properties of the release film. For example, a corona treatment, a normal temperature plasma treatment, or a saponification treatment can be carried out to decrease the surface energy, and a silicone treatment, a fluorine treatment, an olefin treatment, or the like can be carried out to raise the surface energy.

### —Peeling Force Between Wavelength Selective Absorption Filter and Release Film—

In a case where the wavelength selective absorption filter according to the embodiment of the present invention is formed by a coating method, the peeling force between the wavelength selective absorption filter and the release film can be controlled by adjusting the material of the wavelength selective absorption filter, the material of the release film, the internal strain of the wavelength selective absorption filter, and the like. The peeling force can be measured in, for example, a test of peeling off the release film in a direction of 90°, and the peeling force as measured at a speed of 300 mm/min is preferably 0.001 to 5 N/25 mm, more preferably 0.01 to 3 N/25 mm, and still more preferably 0.05 to 1 N/25 mm. In a case where the peeling force is equal to or greater than the above preferable lower limit value, peeling off the release film in a step other than the peeling step can be prevented, and in a case where the peeling force is equal to or smaller than the above preferable upper limit value, peeling failure in the peeling step (for example, zipping and cracking of the wavelength selective absorption filter) can be prevented.

### <Film Thickness of Wavelength Selective Absorption Filter>

The film thickness of the wavelength selective absorption filter according to the embodiment of the present invention is not particularly limited, and it is preferably 1 to 18 μm, more preferably 1 to 12 μm, and still more preferably 1 to 8 μm. In a case where the film thickness is equal to or smaller than the above-described preferred upper limit value, the decrease in the degree of polarization due to the fluorescence emitted by a dye (a coloring agent) can be suppressed by adding the dye to the thin film at a high concentration. In addition, the effects of the quencher and the antifading agent are easily exhibited. On the other hand, in a case where the film thickness is equal to or larger than the above-described preferred lower limit value, it is easy to maintain the evenness of the in-plane absorbance.

In the present invention, the film thickness of 1 to 18 μm means that the thickness of the wavelength selective absorption filter is within a range of 1 to 18 μm even in a case where the thickness is measured at any portion. The same applies to the film thicknesses of 1 to 12 μm and 1 to 8 μm. The film thickness can be measured with an electronic micrometer (for example, manufactured by Anritsu Corporation).

### <Absorbance of Wavelength Selective Absorption Filter>

In the wavelength selective absorption filter according to the embodiment of the present invention, the maximum absorbance exhibited by the dye A is usually preferably 0.01 to 1 and more preferably 0.1 to 0.6.

In addition, it is preferable that the maximum absorbance exhibited by the dye A is small with respect to any of the maximum absorbances exhibited by dyes having a main absorption wavelength range in a short wavelength range of the main absorption wavelength range of the dye A, that is, a wavelength range of less than 600 nm (hereinafter, referred to as “maximum absorbance of other dyes”). That is, the ratio of the maximum absorbance exhibited by the dye A to the maximum absorbance of other dyes is preferably less than 1 even between the dye A and any dye having a main absorption wavelength range in a wavelength range of less than 600 nm.

In addition, in a relationship between the dye exhibiting the highest absorbance among the maximum absorbances of other dyes and the dye A, the ratio of the maximum absorbance exhibited by the dye A to the maximum absorbance of other dyes is more preferably 0.001 to 0.8 and still more preferably 0.01 to 0.5. The dye exhibiting the highest absorbance among the maximum absorbances of other dyes is not particularly limited, but is usually the dye D.

Regarding the spectra of the wavelength selective absorption filters Nos. 101 to 107 and the laminate No. 108 produced in Examples, the ratio of the maximum absorbance exhibited by the dye A to the maximum absorbance of other dyes in a relationship between the dye D exhibiting the highest absorbance among the maximum absorbances of other dyes and the dye A is as follows.

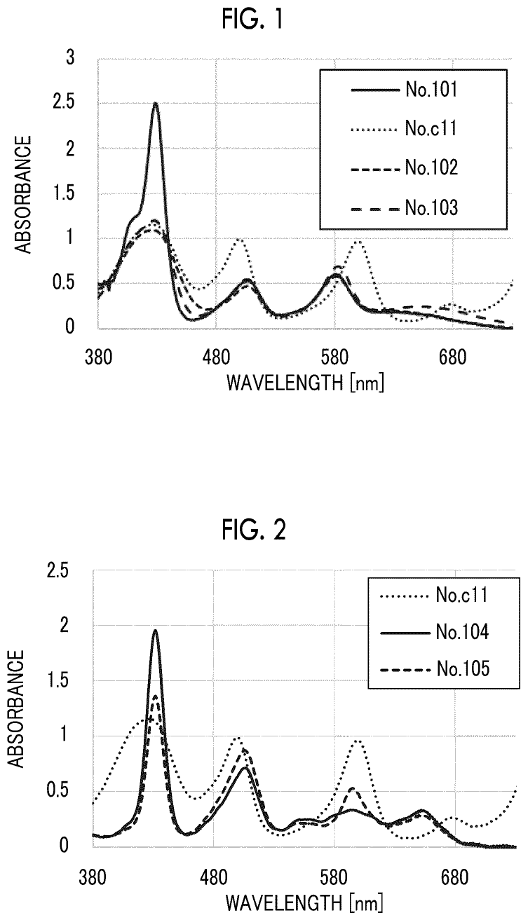

In the absorption spectrum of the wavelength selective absorption filter No. 101 produced in Example shown in FIG. 1 below, the maximum absorbance exhibited by the dye A is 0.18, and the ratio of the maximum absorbance exhibited by the dye A to the maximum absorbance of other dyes is 0.072. In addition, in the absorption spectrum of the wavelength selective absorption filter No. 102 produced in Example shown in FIG. 1 below, the maximum absorbance exhibited by the dye A is 0.20, and the ratio of the maximum absorbance exhibited by the dye A to the maximum absorbance of other dyes is 0.19. In addition, in the absorption spectrum of the wavelength selective absorption filter No. 103 produced in Example shown in FIG. 1 below, the maximum absorbance exhibited by the dye A is 0.24, and the ratio of the maximum absorbance exhibited by the dye A to the maximum absorbance of other dyes is 0.20.

In addition, in the absorption spectrum of the wavelength selective absorption filter No. 104 produced in Example shown in FIG. 2 below, the maximum absorbance exhibited by the dye A is 0.33, and the ratio of the maximum absorbance exhibited by the dye A to the maximum absorbance of other dyes is 0.17. In addition, in the absorption spectrum of the wavelength selective absorption filter No. 105 produced in Example shown in FIG. 2 below, the maximum absorbance exhibited by the dye A is 0.29, and the ratio of the maximum absorbance exhibited by the dye A to the maximum absorbance of other dyes is 0.21.

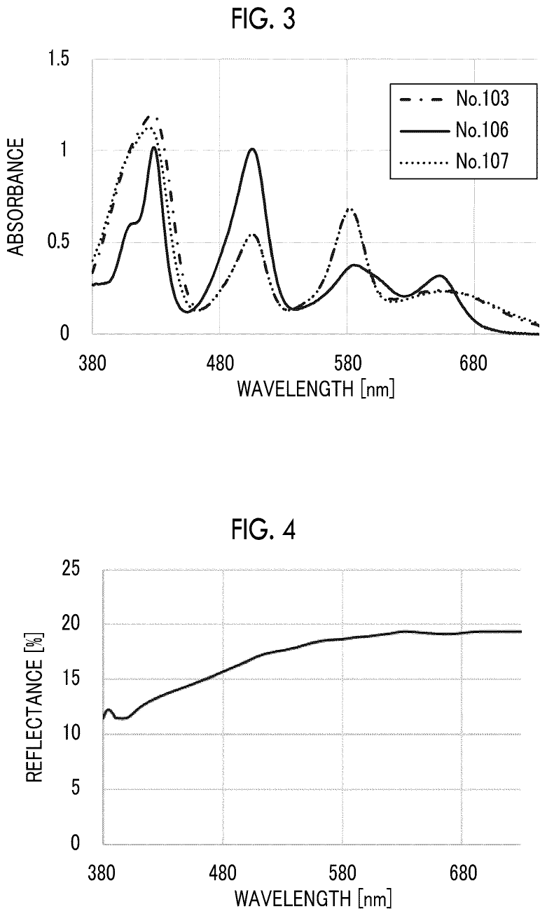

In addition, in the absorption spectrum of the wavelength selective absorption filter No. 106 produced in Example shown in FIG. 3 below, the maximum absorbance exhibited by the dye A is 0.32, and the ratio of the maximum absorbance exhibited by the dye A to the maximum absorbance of other dyes is 0.32. In addition, in the absorption spectrum of the wavelength selective absorption filter No. 107 produced in Example shown in FIG. 3 below, the maximum absorbance exhibited by the dye A is 0.23, and the ratio of the maximum absorbance exhibited by the dye A to the maximum absorbance of other dyes is 0.20.

In addition, in the absorption spectrum of the laminate No. 108 produced in Example shown in FIG. 6 below, the maximum absorbance exhibited by the dye A is 0.28, and the ratio of the maximum absorbance exhibited by the dye A to the maximum absorbance of other dyes is 0.16.

### <Moisture Content of Wavelength Selective Absorption Filter>

From the viewpoint of the durability, the moisture content of the wavelength selective absorption filter according to the embodiment of the present invention is preferably 0.5% by mass or less, and more preferably 0.3% by mass or less, in conditions of 25° C. and 80% relative humidity, regardless of the film thickness.

In the specification, the moisture content of the wavelength selective absorption filter can be measured by using a sample having a thick film thickness as necessary. The moisture content can be calculated by humidity-conditioning the sample for 24 hours or longer, then measuring a moisture content (g) by the Karl Fischer method with a water measuring instrument and a sample drying apparatus “CA-03” and “VA-05” (both manufactured by Mitsubishi Chemical Corporation), and dividing the moisture content (g) by the sample mass (g, including the moisture content).

### <Glass Transition Temperature (Tg) of Wavelength Selective Absorption Filter>

The glass transition temperature of the wavelength selective absorption filter according to the embodiment of the present invention is preferably 50° C. to 140° C., more preferably 60° C. to 130° C., and still more preferably 70° C. to 120° C. In a case where the glass transition temperature is equal to or higher than the above preferable lower limit value, deterioration in a case of being used at a high temperature can be suppressed, and in a case where the glass transition temperature is equal to or lower than the above preferable upper limit value, it is possible to suppress that the organic solvent used in the coating liquid easily remains in the wavelength selective absorption filter.

The glass transition temperature of the wavelength selective absorption filter according to the embodiment of the present invention can be measured by the following method.

With a differential scanning calorimetry device (X-DSC7000 (manufactured by IT Measurement Control Co., Ltd.)), 20 mg of a wavelength selective absorption filter is placed in a measurement pan, and the temperature of the pan is raised from 30° C. to 120° C. in a nitrogen stream at a speed of 10° C./min, and held for 15 minutes, and then cooled to 30° C. at −20° C./min. Thereafter, the temperature was raised again from 30° C. to 250° C. at a rate of 10° C./min, and the temperature at which the baseline began to deviate from the low temperature side was defined as the glass transition temperature Tg. The glass transition temperature of the wavelength selective absorption filter according to the embodiment of the present invention can be adjusted by mixing two or more kinds of polymers having different glass transition temperatures, or by changing the amount of a low-molecular-weight compound such as an antifading agent added.

### <Treatment of Wavelength Selective Absorption Filter>

The wavelength selective absorption filter may be subjected to a hydrophilic treatment by a glow discharge treatment, a corona discharge treatment, an alkali saponification treatment, or the like, where a corona discharge treatment is preferably used. It is also preferable to apply the method disclosed in JP1994-094915A (JP-H06-094915A) and JP1994-118232A (JP-H06-118232A).

If necessary, the obtained film may be subjected to a heat treatment step, a superheated steam contact step, an organic solvent contact step, or the like. In addition, a surface treatment may be suitably performed.

In addition, as a pressure sensitive adhesive layer, a layer consisting of a pressure-sensitive adhesive composition in which a (meth)acrylic resin, a styrene-based resin, a silicone-based resin, or the like is used as a base polymer, and a crosslinking agent such as an isocyanate compound, an epoxy compound, or an aziridine compound is added thereto can be applied.

Preferably, the description regarding the pressure sensitive adhesive layer in the OLED display device described later can be applied.

A predetermined optical film may be attached to the wavelength selective absorption filter according to the embodiment of the present invention.

The predetermined optional optical film is not particularly limited in terms of any of optical properties and materials, and a film containing (or containing as a main component) at least any of a cellulose ester resin, an acrylic resin, a cyclic olefin resin, and a polyethylene terephthalate resin can be preferably used. An optically isotropic film or an optically anisotropic retardation film may be used.

For the above optional optical films, for example, Fujitac TD80UL (manufactured by FUJIFILM Corporation) or the like can be used as a film containing a cellulose ester resin.

Regarding the optional optical film, as those containing an acrylic resin, an optical film containing a (meth)acrylic resin containing a styrene-based resin described in JP4570042B, an optical film containing a (meth)acrylic resin having a glutarimide ring structure in a main chain described in JP5041532B, an optical film containing a (meth)acrylic resin having a lactone ring structure described in JP2009-122664A, and an optical film containing a (meth)acrylic resin having a glutaric anhydride unit described in JP2009-139754A can be used.

Further, regarding the optional optical films, as those containing a cyclic olefin resin, cyclic olefin-based resin film described in paragraphs and subsequent paragraphs of JP2009-237376A, and cyclic olefin resin film containing an additive reducing Rth described in JP4881827B, JP2008-063536B can be used.

The wavelength selective absorption filter according to the embodiment of the present invention may be provided with a gas barrier layer.

The material forming the gas barrier layer is not particularly limited, and for example, an organic material such as polyvinyl alcohol and polyvinylidene chloride, an organic-inorganic hybrid material such as a sol-gel material, and inorganic materials such as SiO₂, SiOₓ, SiON, SiNₓ, and Al₂O₃ can be exemplified. The gas barrier layer may be a single layer or a multi-layer. In the case of a multi-layer, examples thereof include configurations such as an inorganic dielectric multi-layer film and a multi-layer film obtained by alternately laminating organic materials and inorganic materials.

The method for forming the gas barrier layer is not particularly limited. For example, in the case of an organic material, a method by a casing method such as spin coating or slit coating, and a resin gas barrier film can be used as the wavelength selective absorption filter according to the embodiment of the present invention. Examples thereof can include a method of bonding, and in the case of an inorganic material, a plasma enhanced chemical vapor deposition (CVD) method, a sputtering method, a vapor deposition method, and the like are exemplified.

Among the above, in a case of a configuration in which the gas barrier layer contains a crystalline resin, the gas barrier layer contains a crystalline resin, and it is preferable that the thickness of the layer is 0.1 μm to 10 μm and the oxygen permeability of the layer is 60 cc/m²·day·atm or less.

In the gas barrier layer, the “crystalline resin” is a resin having a melting point that undergoes a phase transition from a crystal to a liquid in a case where the temperature is raised, and it can impart gas barrier properties related to oxygen gas to the gas barrier layer.

Examples of the crystalline resin include polyvinyl alcohol and polyvinylidene chloride, and the polyvinyl alcohol is preferable from the viewpoint that a crystalline portion can effectively suppress the permeation of gas.

“The gas barrier layer containing a crystalline resin, where the thickness of the layer is 0.1 μm to 10 μm and the oxygen permeability of the layer is 60 cc/m²·day·atm or less” described above is the same as the gas barrier layers described in to of WO2022/149510A, and these descriptions can be applied as they are.

In a case where the gas barrier layer is provided in the wavelength selective absorption filter according to the embodiment of the present invention, examples thereof include a method of directly producing the above-described gas barrier layer on the wavelength selective absorption filter according to the embodiment of the present invention, which is produced by the above-described manufacturing method. In this case, it is also preferable that a surface of the wavelength selective absorption filter according to the embodiment of the present invention, on which the gas barrier layer is provided, is subjected to a corona treatment.

The wavelength selective absorption filter according to the embodiment of the present invention can achieve both the suppression of a decrease in brightness and the suppression of the influence of the reflection tint on the inherent tint of the display image (hereinafter, also simply referred to as “suppression of the influence of the reflection tint”) at a high level in any case of being applied to an OLED display device not having a color filter or an OLED display device having a color filter, and can be suitably applied to a display device regardless of the presence or absence of the color filter.

### [OLED Display Device]

The OLED display device according to the embodiment of the present invention includes the wavelength selective absorption filter according to the embodiment of the present invention.

As another configuration of the OLED display device according to the embodiment of the present invention, the configuration of the generally used OLED display device can be used without particular limitation, as long as the wavelength selective absorption filter according to the embodiment of the present invention is included.

A configuration example of the OLED display device according to the embodiment of the present invention is not particularly limited, and examples of a configuration having a color filter include a display device including, in order from a side opposite to external light, glass, a layer including a thin film transistor (TFT), an OLED display element, a barrier film, a color filter, glass, a pressure sensitive adhesive layer, the wavelength selective absorption filter according to the embodiment of the present invention, and a surface film.

In addition, examples of a configuration not having a color filter include a display device including, in order from a side opposite to external light, glass, a layer including a thin film transistor (TFT), an OLED display element, a barrier film, glass, a pressure sensitive adhesive layer, the wavelength selective absorption filter according to the embodiment of the present invention, and a surface film.

In a case where the wavelength selective absorption filter according to the embodiment of the present invention has a gas barrier layer, in the above-described configuration example of the OLED display device according to the embodiment of the present invention, the gas barrier layer with respect to the wavelength selective absorption filter according to the embodiment of the present invention may be disposed on the external light side or on the side opposite to the external light, and is preferably disposed on the external light side.

The above-described OLED display element has a configuration in which an anode electrode, a light emitting layer, and a cathode electrode are laminated in this order. In addition to the light emitting layer, a hole injection layer, a hole transport layer, an electron transport layer, an electron injection layer, or the like is included between the anode electrode and the cathode electrode. In addition, for example, the description in JP2014-132522A can also be referenced.

Further, as the color filter, in addition to a normal color filter, a color filter in which quantum dots are laminated can also be used.

A resin film can be used instead of the above-described glass.

The OLED display device according to the embodiment of the present invention includes the wavelength selective absorption filter according to the embodiment of the present invention, and thus, the external light reflection can be suppressed by the dye contained in the filter, and both the suppression of the decrease in brightness and the suppression of the influence of the reflection tint on the inherent tint of the display image (that is, the suppression of the tint change of the display image) can be realized at a high level. That is, an antireflection film is usually used as the surface film. However, by adopting the wavelength selective absorption filter according to the embodiment of the present invention, the OLED display device according to the embodiment of the present invention can achieve the excellent effect without using the antireflection film. It should be noted that it does not interfere with the combination use of the antireflection film, as the configuration of the OLED display device according to the embodiment of the present invention, within the range not impairing the effects of the present invention.

A method of forming a color image of the OLED that can be applied to the OLED display device according to the embodiment of the present invention is not particularly limited, and any of a three-color separation method of red (R), green (G), and blue (B), a color conversion method using quantum dots (QD) or the like, and a color filter method using a white OLED can be used. Therefore, as the light source of the OLED display device according to the embodiment of the present invention, each light emitting layer corresponding to the above image forming method can be applied.

### <Pressure Sensitive Adhesive Layer>

In the OLED display device according to the embodiment of the present invention, it is preferable that the wavelength selective absorption filter according to the embodiment of the present invention is bonded to glass via a pressure sensitive adhesive layer.

For the pressure sensitive adhesive layer, the descriptions related to the pressure sensitive adhesive layer and the forming method in the OLED display device, which are described in paragraphs to of WO2021/014973A, can be applied as they are.

### <Substrate>

In the OLED display device according to the embodiment of the present invention, it is preferable that the wavelength selective absorption filter according to the embodiment of the present invention is bonded to glass via a pressure sensitive adhesive layer.

The method of forming the pressure sensitive adhesive layer is not particularly limited, and for example, a method of applying the pressure sensitive adhesive composition to the wavelength selective absorption filter according to the embodiment of the present invention by a general means such as a bar coater, drying, and curing the pressure sensitive adhesive composition; a method of applying the pressure sensitive adhesive composition first to the surface of a peelable substrate, and drying the composition, and then transferring the pressure sensitive adhesive layer using the peelable substrate to the wavelength selective absorption filter according to the embodiment of the present invention and then aging and curing the composition can be used.

The peelable substrate is not particularly limited, and a predetermined peelable substrate can be used. For example, the release film in the manufacturing method of the wavelength selective absorption filter according to the embodiment of the present invention described above is exemplified.

In addition, the conditions of application, drying, aging, and curing can be appropriately adjusted based on a conventional method.

### —Substituent Group T—

In addition, in the present invention, in a case where the substituent is simply described as a substituent, the description of the corresponding substituent in the substituent group T can be referred to and applied. For example, in a case where only “alkyl group” is simply described, the description of “alkyl group” in the substituent group T can be referred to and applied. The same applies to other substituents other than “alkyl group”.

In addition, in the present invention, examples of the substituent which may be contained in a certain substituent such as an “alkyl group” include a substituent selected from the following substituent group T. In addition, in a case where a certain substituent such as an “alkyl group” has a substituent and further has a substituent, examples of the substituent which is contained in a certain substituent include a substituent obtained by a combination of two or more substituents selected from the following substituent group T.

Furthermore, in the present invention, in a case where an alkyl group is described to be distinguished from a cyclic (cyclo)alkyl group, the alkyl group is used in the sense of including a linear alkyl group and a branched alkyl group. On the other hand, in a case where an alkyl group is not described to be distinguished from a cyclic alkyl group, and unless otherwise specified, the alkyl group is used in the sense of including a linear alkyl group, a branched alkyl group, and a cycloalkyl group. The same applies to a group (an alkoxy group, an alkylthio group, an alkoxycarbonyl group, an alkylthiocarbonyl group, an alkylsulfonyl group, or the like) including a group (an alkyl group, an alkenyl group, an alkynyl group, or the like) which can adopt a cyclic structure, and a compound including a group which can adopt a cyclic structure. In a case where the group can form a cyclic skeleton, the lower limit of the number of atoms in the group forming the cyclic skeleton is 3 or more, preferably 4 or more, and more preferably 5 or more, regardless of the lower limit of the number of atoms specifically described below for the group that can adopt this structure.

In the description of the substituent group T below, a group having a linear or branched structure and a group having a cyclic structure are sometimes described separately, for example, an alkyl group and a cycloalkyl group, in order to clearly distinguish between the group having a linear or branched structure and the group having a cyclic structure.

The groups included in the substituent group T include the following groups.

An alkyl group (preferably having 1 to 30 carbon atoms, more preferably 1 to 20 carbon atoms, still more preferably 1 to 12 carbon atoms, still more preferably 1 to 8 carbon atoms, still more preferably 1 to 6 carbon atoms, and particularly preferably 1 to 3 carbon atoms), an alkenyl group (preferably having 2 to 30 carbon atoms, more preferably 2 to 20 carbon atoms, still more preferably 2 to 12 carbon atoms, still more preferably 2 to 6 carbon atoms, and even still more preferably 2 to 4 carbon atoms), an alkynyl group (preferably having 2 to 30 carbon atoms, still more preferably 2 to 20 carbon atoms, still more preferably 2 to 12 carbon atoms, still more preferably 2 to 6 carbon atoms, and even still more preferably 2 to 4 carbon atoms), a cycloalkyl group (preferably having 3 to 20 carbon atoms), a cycloalkenyl group (preferably having 4 to 20 carbon atoms), and an aryl group (may be a monocyclic group or a fused ring group (preferably a fused group of 2 to 6 rings). In a case of a fused ring group, the fused ring group is preferably a 6- or 8-membered ring, and more preferably a 6-membered ring. The monocyclic ring is preferably a 6-membered ring. The aryl group preferably has 6 to 40 carbon atoms, more preferably has 6 to 30 carbon atoms, still more preferably has 6 to 26 carbon atoms, and particularly preferably has 6 to 10 carbon atoms), a heterocyclic group (which may be a group having at least one nitrogen atom, oxygen atom, sulfur atom, phosphorus atom, silicon atom, or selenium atom (preferably at least one oxygen atom, sulfur atom, or nitrogen atom) as a ring-constituting atom, and may be a monocyclic group or a fused ring group (preferably a fused ring group having 2 to 6 rings). The number of ring members in the ring in the monocyclic group and the ring constituting the fused ring group is preferably 5 to 7, and more preferably 5 or 6. The number of carbon atoms in the heterocyclic group is preferably 2 to 40, and more preferably 2 to 20. The heterocyclic group includes an aromatic heterocyclic group (a heteroaryl group) and an aliphatic heterocyclic group (an aliphatic heterocyclic group), an alkoxy group (preferably having 1 to 20 carbon atoms, more preferably having 1 to 12 carbon atoms, still more preferably having 1 to 8 carbon atoms, even still more preferably having 1 to 6 carbon atoms, and particularly preferably having 1 to 3 carbon atoms), an alkenyloxy group (preferably having 2 to 20 carbon atoms and more preferably having 2 to 12 carbon atoms), an alkynyloxy group (preferably having 2 to 20 carbon atoms and more preferably having 2 to 12 carbon atoms), a cycloalkyloxy group (preferably having 3 to 20 carbon atoms), an aryloxy group (preferably having 6 to 40 carbon atoms, more preferably having 6 to 26 carbon atoms, and still more preferably having 6 to 14 carbon atoms), a heterocyclic oxy group (preferably having 2 to 20 carbon atoms), a polyalkyleneoxy group.

An alkoxycarbonyl group (preferably having 2 to 20 carbon atoms, more preferably having 2 to 12 carbon atoms, and still more preferably having 2 to 8 carbon atoms), a cycloalkoxycarbonyl group (preferably having 4 to 20 carbon atoms, more preferably having 4 to 14 carbon atoms, and still more preferably having 4 to 10 carbon atoms), an alkoxycarbonylthio group (preferably having 2 to 20 carbon atoms), an aryloxycarbonyl group (preferably having 6 to 20 carbon atoms, more preferably having 6 to 16 carbon atoms, and still more preferably having 6 to 12 carbon atoms), an arylthiocarbonyl group (preferably having 6 to 20 carbon atoms), an amino group (preferably having 0 to 20 carbon atoms, more preferably having 0 to 12 carbon atoms, still more preferably having 0 to 8 carbon atoms, even more preferably having 0 to 6 carbon atoms, and particularly preferably having 0 to 3 carbon atoms. An unsubstituted amino group (—NH₂), as well as a mono- or di-substituted amino group substituted with a group selected from an alkyl group, an alkenyl group, an alkynyl group, a cycloalkyl group, a cycloalkenyl group, an aryl group, and a heterocyclic group. The above-described groups that substitute the unsubstituted amino group have the same meaning as the corresponding groups in the substituent group T), a sulfamoyl group (preferably having 0 to 20 carbon atoms, and an alkyl, cycloalkyl, or aryl sulfamoyl group is preferable), an acyl group (preferably having 1 to 20 carbon atoms and more preferably having 2 to 15 carbon atoms, and including-C(═O) H, an alkylcarbonyl group, a cycloalkylcarbonyl group, an arylcarbonyl group, and a heterocyclic carbonyl group), an acyloxy group (preferably having 1 to 20 carbon atoms, more preferably having 1 to 12 carbon atoms, and still more preferably having 1 to 8 carbon atoms), a carbamoyl group (preferably having 1 to 20 carbon atoms, more preferably having 1 to 12 carbon atoms, and still more preferably having 1 to 8 carbon atoms, and an alkyl, cycloalkyl, or aryl carbamoyl group is preferable);

An acylamino group (preferably having 1 to 20 carbon atoms, more preferably having 1 to 12 carbon atoms, and still more preferably having 1 to 8 carbon atoms, and including an alkylcarbonylamino group, a cycloalkylcarbonylamino group, an arylcarbonylamino group, and a heterocyclic carbonylamino group), a sulfonamide group (preferably having 0 to 20 carbon atoms, more preferably having 0 to 12 carbon atoms, and still more preferably having 0 to 8 carbon atoms, and an alkyl, cycloalkyl, or aryl sulfonamide group is preferable), an alkylthio group (preferably having 1 to 20 carbon atoms, and more preferably having 1 to 12 carbon atoms), a cycloalkylthio group (preferably having 3 to 20 carbon atoms), an arylthio group (preferably having 6 to 40 carbon atoms, more preferably having 6 to 26 carbon atoms, and still more preferably having 6 to 14 carbon atoms), a heterocyclic thio group (preferably having 2 to 20 carbon atoms), an alkyl, cycloalkyl, or aryl sulfonyl group (preferably having 1 to 20 carbon atoms), and an aminosulfonyl group (for the amino group in the aminosulfonyl group, the description of the amino group in the above-described substituent group T can be applied);

A silyl group (preferably having 1 to 30 carbon atoms and more preferably 1 to 20 carbon atoms; preferably a silyl group at which an alkyl, aryl, alkoxy, or aryloxy has been substituted), a silyloxy group (preferably having 1 to 20 carbon atoms: preferably a silyloxy group at which an alkyl, aryl, alkoxy, or aryloxy has been substituted), a hydroxy group, a cyano group, a nitro group, a halogen atom (for example, a fluorine atom, a chlorine atom, a bromine atom or an iodine atom), an oxygen atom (specifically replacing >CH₂ which constitutes a ring with >C═O), a carboxy group (—CO₂H), a phosphono group [—PO(OH)₂], a phosphonooxy group [—O—PO(OH)₂], a sulfo group (—SO₃H), a boric acid group [—B(OH)₂], onio group (referred to as a cationic group. The onio group includes an ammonio group including a cyclic ammonio group, a sulfonio group, and a phosphono group, preferably having 0 to 30 carbon atoms and more preferably having 1 to 20 carbon atoms), a sulfanyl group (—SH), and a guanidino group (—NHC(═NH)NH₂).

The substituents selected from the substituent group T include not only groups obtained by combining a plurality of substituents selected from the above-mentioned substituent group T, but also groups obtained by combining a plurality of the above-mentioned groups, unless otherwise specified. For example, in a case where a compound, a substituent, or the like contains an alkyl group, an alkenyl group, or the like, the alkyl group, the alkenyl group, or the like may be substituted or unsubstituted. In addition, in a case where a compound, a substituent, or the like contains an aryl group, a heterocyclic group, or the like, the aryl group, the heterocyclic group, or the like may be a monocyclic ring or a fused ring, and may be substituted or unsubstituted.

### EXAMPLES

Hereinafter, the present invention will be more specifically described based on examples. Materials, using amounts, proportions, treatment details, treatment content, and the like shown in the following examples can be appropriately changed without departing from the gist of the present invention. Therefore, it is to be understood that the scope of the present invention is not limited to Examples described below.

In the following examples, “parts” and “%” representing the composition are based on mass unless otherwise specified. Further, λₘₐₓ means the maximal absorption wavelength showing the maximum absorbance.

### [Production of Wavelength Selective Absorption Filter]

The materials used in the production of the wavelength selective absorption filter are shown below.

### <Matrix Resin>

### (Resin 1)

Polybenzyl methacrylate resin (manufactured by Sigma-Aldrich Co., LLC) was used as the resin 1.

### (Resin 2)

Polystyrene resin (manufactured by PS Japan Corporation, PSJ-polystyrene GPPS SGP-10 (product name)) was heated at 110° C. and allowed to cool to normal temperature (23° C.), and the cooled resin was used as the resin 2.

### (Resin 3)

Arton R5000 (product name, manufactured by JSR Corporation, norbornene-based polymer, Tg: 135° C.), which is a cyclic polyolefin resin, was used as the resin 3.

### (Resin 4)

EXCEVAL AQ-4104 (product name, manufactured by Kuraray Co., Ltd., modified polyvinyl alcohol (crystalline resin), saponification degree: 98 to 99 mol %) was used as the resin 4.

### <Dye>

As the dye, each dye described below was used. In the following structural formulae, Ph means a phenyl group, and i-means iso-. It is noted that λₘₐₓ described in the section of the following dyes means λₘₐₓ exhibited by each dye in the wavelength selective absorption filter measured by a method described later.

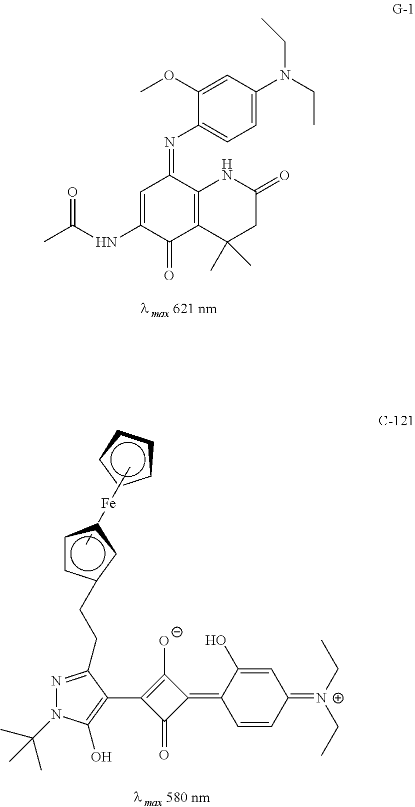

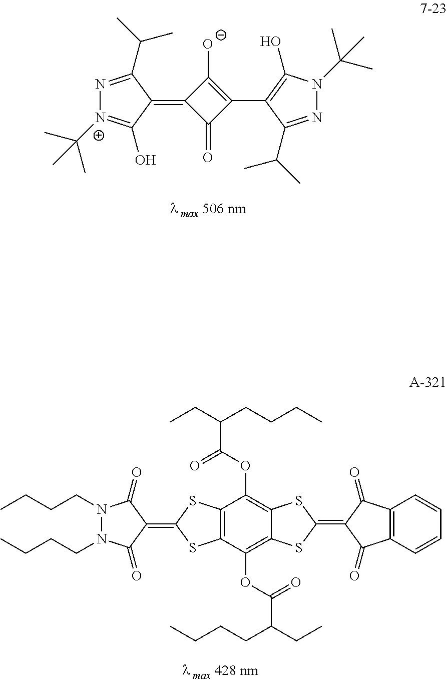

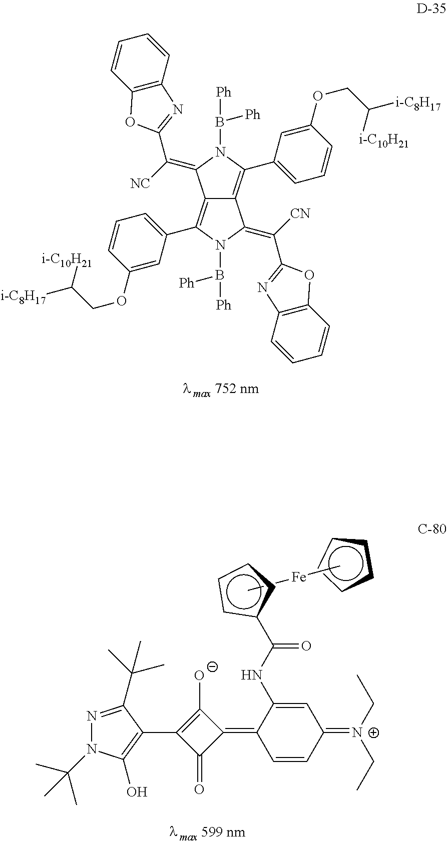

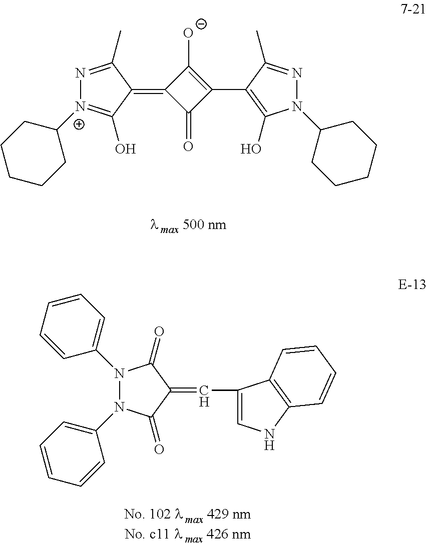 [SMILES: CC1=N[N+](C2CCCCC2)=C(O)/C1=C1\C(=O)C(c2c(C)nn(C3CCCCC3)c2O)=C1[O-] ; O=C1C(=Cc2c[nH]c3ccccc23)C(=O)N(c2ccccc2)N1c1ccccc1]

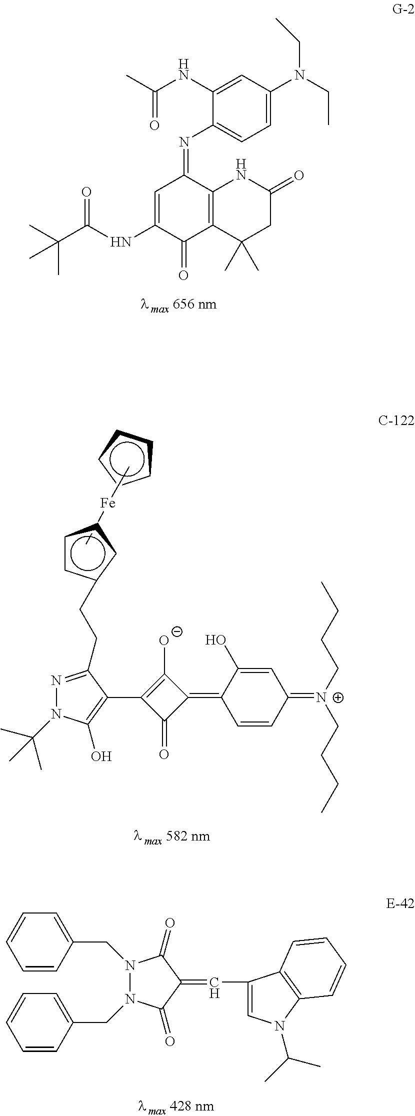

Solvent Blue 35 (manufactured by FUJIFILM Wako Pure Chemical Corporation, anthraquinone dye, λₘₐₓ: 652 nm) was used as a dye H-1.

FDG-007 (product name, manufactured by Yamada Chemical Co., Ltd., tetraazaporphyrin copper complex dye, λₘₐₓ: 594 nm) was used as a dye I-1.

PD-311F (product name, manufactured by Yamamoto Chemicals, Inc., tetraazaporphyrin copper complex dye, λₘₐₓ: 585 nm) was used as a dye I-2.

FDB-002 (product name, manufactured by Yamada Chemical Co., Ltd., porphyrin vanadium complex dye, λₘₐₓ: 432 nm) was used as a dye J-1.

### (Leveling Agent 1)

A polymer surfactant composed of the following constitutional components was used as a leveling agent 1. In the following structural formulae, a proportion of each constitutional component is a molar ratio, and t-Bu means a tert-butyl group.

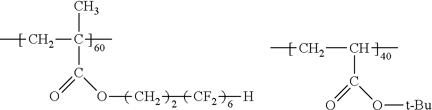

### (Substrate 1)

A polyethylene terephthalate film (manufactured by TORAY INDUSTRIES, Inc., product name: Lumirror XD-510P, film thickness: 50 μm)

### (1) Preparation of Wavelength Selective Absorption Layer Forming Liquid A

Each component was mixed according to the composition shown below to prepare a wavelength selective absorption layer forming liquid A.

Composition of wavelength selective
absorption layer forming liquid A

| | | |
|---|---|---|
| Resin 1 | 89.0 | parts by mass |
| Leveling agent 1 | 0.2 | parts by mass |
| Dye G-1 | 1.4 | parts by mass |
| Dye C-121 | 0.8 | parts by mass |
| Dye 7-23 | 1.1 | parts by mass |
| Dye A-321 | 7.5 | parts by mass |
| Toluene (solvent) | 660.0 | parts by mass |
| Cyclohexanone (solvent) | 73.3 | parts by mass |

Subsequently, the obtained wavelength selective absorption layer forming liquid A was filtered using a filter paper (#63, manufactured by Toyo Filter Paper Co., Ltd.) having an absolute filtration precision of 10 μm, and further filtered using a metal sintered filter (FH025, manufactured by Pall) with an absolute filtration precision of 2.5 μm.

### (2) Production of Substrate-Attached Wavelength Selective Absorption Filter No. 101

The wavelength selective absorption layer forming liquid A after the filtration treatment was applied onto the substrate 1 by using a bar coater so that the film thickness after drying was 2.4 μm, and dried at 120° C. to produce a substrate-attached wavelength selective absorption filter No. 101.

(3) Production of Substrate-Attached Wavelength Selective Absorption Filters No. 102 to 107, c11, and r01

Substrate-attached wavelength selective absorption filters No. 102 to 107 and r01 were produced in the same manner as in the production of the substrate-attached wavelength selective absorption filter No. 101, except that at least any of the type of the dye, the formulation amount of the dye, or the type of the resin was changed to the contents shown in Table 1 below. The formulation amount of the leveling agent 1 in the substrate-attached wavelength selective absorption filter No. 101 was fixed, the formulation amount of the resin was changed according to the change in the formulation amount of the dye, and the mass of the entire filter was adjusted to be unchanged.

The substrate-attached wavelength selective absorption filter No. c11 was produced in the same manner as the substrate-attached wavelength selective absorption filter No. 101, except that, instead of the wavelength selective absorption layer forming liquid A, a wavelength selective absorption filter forming liquid Ba-1 described in paragraph of WO 2021/014973, from which the antifading agent IV-8 was removed, was used, and, while fixing the content ratios of the resin 1 (a resin corresponding to the above-described resin 2, obtained by heating a polystyrene resin (manufactured by PS Japan Corporation, PSJ-polystyrene GPPS SGP-10 (product name)) at 110° C. and allowing the polystyrene resin to cool to normal temperature (23° C.)), the resin 2 (a polyphenylene ether resin (manufactured by Asahi Kasei Corporation, ZYLON S201A (product name), poly(2,6-dimethyl-1,4-phenylene oxide))), the extensible resin component 1 (ASAFLEX 810 (product name, manufactured by Asahi Kasei Corporation, a styrene-butadiene resin)), the peelability control resin component 1 (VYLON 550 (product name, manufactured by Toyobo Co., Ltd., a polyester-based additive)), and the leveling agent 1, the formulation amount of the dye was changed to the contents shown in Table 1 below.

### (4) Production of Laminate No. 108

### (i) Production of Substrate-Attached Wavelength Selective Absorption Filter No. 108

A substrate-attached wavelength selective absorption filter No. 108 was produced in the same manner as in the production of the substrate-attached wavelength selective absorption filter No. 101, except that the type of the dye, the formulation amount of the dye, and the type of the resin were changed to the contents shown in Table 1 below. The formulation amount of the leveling agent 1 in the substrate-attached wavelength selective absorption filter No. 101 was fixed, the formulation amount of the resin was changed according to the change in the formulation amount of the dye, and the mass of the entire filter was adjusted to be unchanged.

Furthermore, the wavelength selective absorption layer side (the side opposite to the substrate 1) of the substrate-attached wavelength selective absorption filter No. 108 was subjected to a corona treatment under the conditions of a discharge amount of 1,000 W·min/m² and a treatment speed of 3.2 m/min using a corona treatment device (product name: Corona-Plus, manufactured by VETAPHONE).

### (ii) Preparation of Gas Barrier Layer Forming Liquid

Each component was mixed according to the composition shown below, and the mixture was stirred in a constant-temperature tank at 90° C. for 1 hour to dissolve the resin 4 to prepare a gas barrier layer forming liquid 1.

Composition of gas barrier layer forming liquid 1

| | |
|---|---|
| Resin 4 | 4.0 parts by mass |
| Pure water | 96.0 parts by mass |

Subsequently, the obtained gas barrier layer forming liquid 1 was filtered using a filter having an absolute filtration precision of 5 μm (product name: Hydrophobic Fluorophore Membrane, manufactured by Millex).

(iii) Production of Laminate

The gas barrier layer forming liquid 1 after the filtration treatment was applied onto a surface (wavelength selective absorption layer) of the substrate-attached wavelength selective absorption filter No. 108, which had been subjected to a corona treatment, using a bar coater such that a film thickness after drying was 1.6 μm, and dried at 130° C. for 60 seconds to form a gas barrier layer, thereby producing a laminate No. 108.

This laminate No. 108 has a structure in which the substrate 1, the wavelength selective absorption layer, and the gas barrier layer are laminated in this order.

### (5) Production of Laminate No. r02 for Reference

A laminate No. r02 was produced in the same manner as in the production of the laminate No. 108, except that the dye was not added to the substrate-attached wavelength selective absorption filter. The formulation amount of the leveling agent 1 in the substrate-attached wavelength selective absorption filter No. 108 was fixed, and the formulation amount of the resin was changed in accordance with the change in the formulation amount of the dye, and the adjustment was carried out such that the mass of the entire filter was not changed.

The substrate-attached wavelength selective absorption filters Nos. 101 to 107 and the laminate No. 108 are the substrate-attached wavelength selective absorption filter according to the embodiment of the present invention and the laminate including the substrate-attached wavelength selective absorption filter according to the embodiment of the present invention, the substrate-attached wavelength selective absorption filter No. c11 is a comparative substrate-attached wavelength selective absorption filter, the substrate-attached wavelength selective absorption filter No. r01 is a reference substrate-attached wavelength selective absorption filter containing no dye, and the laminate No. r02 is a reference laminate containing no dye.

### <Maximal Absorption Value of Wavelength Selective Absorption Filter>

Using a UV3150 spectrophotometer (product name) manufactured by Shimadzu Corporation, an absorbance of the substrate-attached wavelength selective absorption filter in a wavelength range of 380 to 780 nm was measured every 1 nm. An absorbance difference between an absorbance Abₓ (λ) at each wavelength λ nm of the substrate-attached wavelength selective absorption filter and Ab₀ (λ) of the substrate-attached wavelength selective absorption filter (that is, the wavelength selective absorption filter No. r01) that does not contain dye, which is Abₓ (λ)−Ab₀ (λ), was calculated, and the maximum value of the absorbance difference was defined as the maximal absorption value. Since there is no difference in the absorbance Ab₀ (λ) due to the difference between the resin types 1 and 2, the wavelength selective absorption filter No. r01 for reference is also used for the wavelength selective absorption filters Nos. c11 and 104 to 107.

In addition, for the laminate No. 108, an absorbance difference Abₓ (λ)−Ab₀ (λ) with the absorbance Ab₀ (λ) of the laminate containing no dye (that is, the laminate No. r02 for reference) was calculated, and a maximum value of the absorbance difference was defined as an maximal absorption value.

Absorption spectra of the obtained wavelength selective absorption filters Nos. 101 to 107 and c11 and the laminate No. 108 are shown in FIGS. 1 to 3 and 6.

λₘₐₓ of each dye in the wavelength selective absorption filter and the laminate is as described together with the chemical structure of each dye in the section of each dye described above.

### <Simulation of Relative Brightness, Reflectance, and Reflected Tint>

The OLED display device described in (1) below comprising the wavelength selective absorption filter prepared above, was subjected to a simulation of external light reflection, and the reflectance and the reflected tint (a* and b*) were calculated as described in (3) below, and the relative brightness was calculated as described in (4) below. Table 2 below collectively shows combinations of the display device (with a color filter or without a color filter) and the wavelength selective absorption filter used in the simulation, and evaluation results related to the reduction rate of reflectance, the relative brightness, and the reflection tint.

For No. 108, the evaluation was performed using the laminate instead of the substrate-attached wavelength selective absorption filter, and using the laminate No. r02 instead of the wavelength selective absorption filter No. r01 for reference. The substrate-attached wavelength selective absorption filter is applied as a wavelength selective absorption filter from which the substrate has been peeled off, and the laminate is applied as a laminate from which the substrate has been peeled off.

### (1) Configuration of OLED Display Device

### (i) Configuration of OLED Display Device Having Color Filter

As the OLED display device for performing the simulation, a white OLED display device that displays an image using a white OLED element and a color filter was assumed for the OLED display device having a color filter.

That is, the OLED display device having a color filter includes a white OLED element, a color filter (CF), and the wavelength selective absorption filter produced as described above in this order on a TFT substrate. The wavelength selective absorption filter is located on the external light side (visible side). For the laminate of No. 108, the gas barrier layer is located on the external light side (visible side).

Glass is provided between the color filter and the wavelength selective absorption filter, and a surface film is provided on the wavelength selective absorption filter. For the laminate of No. 108, glass is provided between the color filter and the wavelength selective absorption layer, and a surface film is provided on the gas barrier layer.

### (ii) Configuration of OLED Display Device not Having Color Filter

As the OLED display device for performing the simulation, an OLED display device obtained by changing the configuration of the OLED display device having a color filter to a configuration in which a red OLED, a green OLED, and a blue OLED are provided instead of the white OLED in the white OLED element was assumed for the OLED display device not having a color filter.

### (2) Simulation Conditions

In the simulation of the reflectance and the reflection tint, as the reflectance and the reflection spectrum in a case where the wavelength selective absorption filter was not used, a value in a state where a circular polarization plate of XRJ-55A90J (OLED television, product name) manufactured by Sony Corporation was peeled off was used for the OLED display device having a color filter, and a value in a state where a circular polarization plate of iPhone (registered trademark) X (product name, manufactured by Apple Inc.) was peeled off was used for the OLED display device not having a color filter. The reflectance and the reflection spectrum were measured using a spectrophotometer CM-700d (product name, manufactured by Konica Minolta, Inc.).

### (3) Calculation of Reflectance and Reflected Tint

The reflectance and the reflection tint were calculated from the reflection spectrum, the transmission spectrum of the wavelength selective absorption filter measured using a UV3150 spectrophotometer (product name) manufactured by Shimadzu Corporation, and the spectrum of the D65 light source. Specifically, it is as follows.

The reflection spectrum of XRJ-55A90J (product name, manufactured by Sony Corporation) was denoted as R(λ)_{X}, the reflection spectrum of iPhone (registered trademark) X (product name, manufactured by Apple Inc.) was denoted as R(λ)ᵢ, the transmission spectrum of the wavelength selective absorption filter was denoted as T(λ), and the reflection spectrum was calculated by the following expression. In the following expression, R(λ)_{X} or R(λ)ᵢ was used as R(λ).

$$Reflection spectrum = R ( λ ) \times {( T ( λ ) )}^{2}$$

The reflection spectrum of the OLED display device not having a color filter in a case where the wavelength selective absorption filter No. r01 not containing a dye, which was calculated above, was used is shown in FIG. 4, and the reflection spectrum of the OLED display device having a color filter is shown in FIG. 5.

The reflectance (visibility correction) and the reflection tint (a* and b*, D65 light source) were calculated based on the reflection spectrum calculated above.

### (4) Calculation of Relative Brightness

The relative brightness in a case where the wavelength selective absorption filter produced above was used was calculated as follows.

As the OLED display device having a color filter, an emission light spectrum S(λ)_{X} of XRJ-55A90J (product name, manufactured by Sony Corporation) was used, and as the OLED display device not having a color filter, an emission light spectrum S(λ)ᵢ of iPhone (registered trademark) X (product name, manufactured by Apple Inc.) was used.

The brightness in a case where the wavelength selective absorption filter was not used was calculated by visibility correction of the spectra S(λ)_{X} and S(λ)ᵢ, and this brightness was set to 100. The brightness of S(λ)ₓ×T(λ) and the brightness of S(λ)ᵢ×T(λ) in a case where the wavelength selective absorption filter was used were calculated as the relative brightness with respect to the brightness in a case where the wavelength selective absorption filter was not used.

### <Evaluation of Suppressing External Light Reflection>

Using the value of the reflectance obtained in the above-described simulation, the reduction rate of the reflectance was calculated according to the following expression, and the effect of suppressing external light reflection was evaluated.

$$Reduction rate of reflectance = ( ( {R}_{0} - {R}_{1} ) / {R}_{0} ) \times 100 \%$$

R₁: Reflectance in a case where a wavelength selective absorption filter containing a dye is used
R₀: reflectance in a case where a wavelength selective absorption filter No. r01 not containing a dye was used

### <Evaluation of External Light Reflected Tint>

Using the values of a and b* calculated in the above simulation, the color difference was calculated according to the following expression. In the following table, this color difference is described as a reflection tint Δa*b*.

$$( Color difference ) = {[ {( {a}_{1}^{*} - {a}_{0}^{*} )}^{2} + {( {b}_{1}^{*} - {b}_{0}^{*} )}^{2} ]}^{1 / 2}$$

The meaning of each reference numeral in the above expression is as follows.
a*₁: a* in a case where the substrate-attached wavelength selective absorption filter containing a dye was used
a*₀: a* in a case where the substrate-attached wavelength selective absorption filter containing no dye of No. r01 was used
b*₁: b* in a case where the substrate-attached wavelength selective absorption filter containing a dye was used
   b*₀: b* in a case where the substrate-attached wavelength selective absorption filter containing no dye of No. r01 was used

The color difference calculated from the above expression is a practical level of 16.0 or less, a preferred level of 12.0 or less, and a more preferred level of 6.0 or less.

TABLE 1

| Wavelength | Dye | | | | | | | | |
|---|---|---|---|---|---|---|---|---|---|
| selective | | | | | | | | | |
| absorption | Dye A | | Dye B | | Dye C | | Dye D | | |
| filter | | Formulation | | Formulation | | Formulation | | Formulation | |
| No. | Type | amount | Type | amount | Type | amount | Type | amount | Resin |
| 101 | G-1 | 1.4 | C-121 | 0.8 | 7-23 | 1.1 | A-321 | 7.5 | 1 |
| 102 | G-1 | 1.5 | C-121 | 0.7 | 7-23 | 1.0 | E-13 | 4.9 | 1 |
| 103 | G-2 | 1.5 | C-122 | 1.0 | 7-23 | 1.2 | E-42 | 6.1 | 1 |
| 104 | H-1 | 2.4 | C-122 | 0.2 | 7-23 | 1.5 | J-1 | 1.6 | 2 |
| 105 | H-1 | 2.1 | I-1 | 0.8 | 7-23 | 1.9 | J-1 | 1.1 | 2 |
| 106 | H-1 | 2.4 | C-122 | 0.3 | 7-23 | 2.2 | E-42 | 2.9 | 2 |
| 107 | G-2 | 1.5 | C-122 | 1.0 | 7-23 | 1.2 | E-42 | 6.1 | 2 |
| 108 | H-1 | 2.8 | I-2 | 0.6 | 7-23 | 1.1 | J-1 | 2.1 | 3 |
| c11 | D-35 | 3.8 | C-80 | 1.5 | 7-21 | 2.1 | E-13 | 4.9 | 2 |
| r01 | — | — | — | — | — | — | — | — | 1 |
| r02 | — | — | — | — | — | — | — | — | 3 |

TABLE 2

| | | Wavelength selective absorption filter No. | | | | | | | | | |
|---|---|---|---|---|---|---|---|---|---|---|---|
| | | r01 | 101 | 102 | 103 | 104 | 105 | 106 | 107 | 108 | c11 |
| With | Reduction rate of | 0% | 69% | 70% | 70% | 70% | 70% | 70% | 70% | 70% | 71% |
| color | reflectance | | | | | | | | | | |
| filter | Relative brightness | 100% | 53% | 52% | 53% | 57% | 57% | 57% | 53% | 55% | 52% |
| | Reflection tint Δa*b* | 0.0 | 2.0 | 5.5 | 4.7 | 3.6 | 3.3 | 3.4 | 3.7 | 3.2 | 8.0 |
| With no | Reduction rate of | 0% | 71% | 71% | 71% | 70% | 70% | 70% | 71% | 70% | 71% |
| color | reflectance | | | | | | | | | | |
| filter | Relative brightness | 100% | 58% | 58% | 58% | 56% | 55% | 55% | 59% | 57% | 57% |
| | Reflection tint Δa*b* | 0.0 | 4.1 | 11.2 | 4.9 | 0.0 | 0.0 | 0.4 | 2.1 | 2.6 | 28.4 |

### (Notes in Table)

Formulation amount of dye: means the formulation amount of the dye in 100 parts by mass of the wavelength selective absorption filter, and the unit is parts by mass. The notation of “-” in the column of the dye of No. r01 and r02 indicates that the corresponding dye is not contained.

The column of No. 108 in Table 2 shows the results of the laminate No. 108.

The column of the dye A also describes the dye D-35 which does not correspond to the dye A.

With color filter: indicates that the display device used for the simulation is an OLED display device (XRJ-55A90J (product name, manufactured by Sony Corporation)) having a color filter.

Without color filter: indicates that the display device used for the simulation is an OLED display device (iPhone (registered trademark) X (product name, manufactured by Apple Inc.)) having no color filter.

From the results in Table 2 above, the following points can be seen.

In the comparative wavelength selective absorption filter No. c11, the main absorption wavelength range of the dye having the main absorption wavelength range on the longest wavelength side among the dyes contained in the wavelength selective absorption filter is not 600 nm or more and less than 680 nm. In a case where the comparative wavelength selective absorption filter No. c11 was applied to the OLED display device having no color filter, the reflection tint Δa*b* was as large as 28.4, and the influence on the inherent tint of the display image was not suppressed.

On the other hand, the wavelength selective absorption filters Nos. 101 to 107 according to the embodiment of the present invention and the laminate No. 108 including the substrate-attached wavelength selective absorption filter according to the embodiment of the present invention, even in a case where any of these was applied to either the OLED display device having no color filter or the OLED display device having a color filter, the suppression of the decrease in brightness was achieved to be equal to or higher than that of the comparative wavelength selective absorption filter No. c11, and the reflection tint Δa*b* was 11.2 or less in all cases, and the suppression of the influence of the reflection tint on the inherent tint of the display image was realized at a high level.

What is claimed is:

1. A wavelength selective absorption filter comprising:
a resin; and
at least four kinds of dyes having different main absorption wavelength ranges,
wherein among the dyes, a dye A having a main absorption wavelength range on a longest wavelength side has a main absorption wavelength range of 600 nm or more and less than 680 nm, and the wavelength selective absorption filter contains at least three kinds of dyes each having a main absorption wavelength range having main absorption wavelength ranges in a wavelength range of less than 600 nm, as the dyes, other than the dye A among the dyes.

2. The wavelength selective absorption filter according to claim 1,
wherein the dye A is an indoaniline dye represented by General Formula (1), 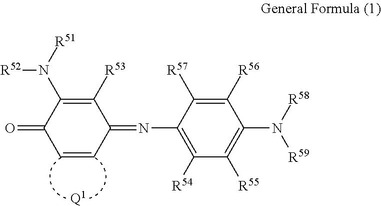
in the formula, Q¹ represents an atomic group that contains at least one nitrogen atom and is necessary for forming a 5- to 7-membered nitrogen-containing heterocyclic ring together with carbon atoms to which Q¹ is bonded,
R⁵¹ represents an acyl group, an alkoxycarbonyl group, an aryloxycarbonyl group, an aminocarbonyl group, or a sulfonyl group, R⁵² represents a hydrogen atom or an alkyl group, R⁵³ to R⁵⁷ represent a hydrogen atom, an alkyl group, an alkoxy group, an acylamino group, an alkylsulfonylamino group, or a halogen atom, R⁵⁸ and R⁵⁹ represent a hydrogen atom, an alkyl group, or an aryl group, and
R⁵¹ and R⁵³, R⁵⁴ and R⁵⁵, and/or R⁵⁵ and R⁵⁹, or R⁵⁸ and R⁵⁹ may be bonded to each other to form a ring.

3. An organic electroluminescent display device comprising:
the wavelength selective absorption filter according to claim 1.
